(19) United States
(12) Patent Application Publication
(10) Pub. No.: US 2010/0127241 A1
(43) Pub. Date: May 27, 2010

(54) Electronic Devices with Carbon Nanotube Components

(75) Inventors: George Gruner, Los Angeles, CA (US); Erika K. Artukovic, Los Angeles, CA (US); David S. Hecht, Santa Monica, CA (US)

Correspondence Address: VENABLE LLP, P.O. BOX 34385, WASHINGTON, DC, 20043-9998, US

(73) Assignee: The Regents of the University of California, Oakland, CA (US)

(21) Appl. No.: 11/885,055

(22) PCT Filed: Feb. 27, 2006
(86) PCT No.: PCT/US06/06610

§ 371 Date: Feb. 2, 2010

Related U.S. Application Data
(60) Provisional application No. 60/656,571, filed on Feb. 25, 2005.

(51) Int. Cl. H01L 29/66; H01L 21/336

(52) U.S. Cl. 257/20; 257/24; 257/9; 438/151; 257/E29.168; 257/E21.411

(57) ABSTRACT

An electronic device has a source electrode, a drain electrode spaced apart from said source electrode, and at least one of a conducting material, dielectric material and a semiconductor material disposed between said source electrode and said drain electrode. At least one of the source electrode, the drain electrode and the semiconductor material includes at least one nanowire.

### CROSS-REFERENCE OF RELATED APPLICATION

This application claims priority to U.S. Provisional Application No. 60/656,571 filed Feb. 25, 2005, the entire contents of which are hereby incorporated by reference.

The U.S. Government has a paid-up license in this invention and the right in limited circumstances to require the patent owner to license others on reasonable terms as provided for by the terms of NSF Grant No. 040429.

### BACKGROUND 1. Field of Invention

This application relates to electronic devices that have components made with nanowires and methods of manufacturing such electronic devices.

2. Discussion of Related Art

The contents of all references, including articles, published patent applications and patents referred to anywhere in this specification are hereby incorporated by reference.

Flexible and transparent transistors have recently resulted is several noteworthy achievements. Transparent transistors have been fabricated using both polymers and inorganic oxides. Both have significant deficiencies. The former have low mobility the latter does not have the desired flexibility and manufacturability characteristics. These factors severely limit the application potential of the devices.

Carbon nanotubes (NTs), because of their excellent electronic properties, have been explored for applications as active electronic devices. Field Effect Transistors (FETs) with NT conducting channels have been fabricated (S. J. Tans, A. R. M. Verschueren, C. Dekker, “Room-temperature transistor based on a single carbon nanotube”, Nature 393, 49-52 (1998); R. Martel, T. Schmidt, H. R. Shea, T. Hertel, and Ph. Avouris, “Single- and multi-wall carbon nanotube field-effect transistors”, Appl Phys Lett 73, 2447-2449 (1998)). Subsequently, it has been shown that a random network of nanotubes with appropriate density can also act as a conducting channel in a FET configuration (K. Bradley, J-C P. Gabriel, A. Star, and G. Grüner, “Short-channel effects in contact-passivated nanotube chemical sensors”, Appl Phys Lett 83, 3821-3823 (2003); J-C P. Gabriel, “Large Scale Production of Carbon Nanotube Transistors: A Generic Platform for Chemical Sensors”, MRS Proceedings Volume 776, Q12.7; E. S. Snow, J. P. Novak, P. M. Campbell, and D. Park, “Random networks of carbon nanotubes as an electronic material”, Appl Phys Lett 82, 2145-2147 (2003)). This has opened up the avenue for a manufacturable device architecture. Room-temperature fabrication techniques enabling flexible transistors have also been explored (K. Bradley, J-C P Gabriel and G. Gruner, “Flexible Nanotube Electronics”, Nano Lett 3,1353 (2003)). It has been shown that due to the high mobility of carbon nanotubes, a network with low sheet resistance is also transparent in the visible spectral range (Z. Wu, Z. Chen, X. Du, J. M. Logan, J. Sippel, M. Nikolou, K. Kamaras, J. R. Reynolds, D. B. Tanner, A. F. Hebard, and A. G. Rinzler, “Transparent, Conductive Carbon Nanotube Films”, Science 305, 1273-1276 (2004); L. Hu, D. S. Hecht and G. Grüner, “Percolation in Transparent and Conducting Carbon Nanotube Networks”, Nano Letters 4, 2523 (2004)).

Transistors that include carbon nanotubes as part of the transistor have been described in U.S. provisional application 60/544,841 (now pending as U.S. application Ser. No. 10/846,072, filed on May 14, 2004).

These disclosures, however, do not cover the architecture where the conducting channel and other conducting media within the architecture (gate, source and drain contacts) are formed by carbon nanotube networks.

### SUMMARY

Further objectives and advantages will become apparent from a consideration of the description, drawings, and examples.

An electronic device according to an embodiment of this invention has a source electrode, a drain electrode spaced apart from the source electrode and at least one of a conducting material, a dielectric material and a semiconductor material disposed between the source electrode and the drain electrode. At least one of the source electrode, the drain electrode and the semiconductor material has at least one nanowire.

In addition, devices according to embodiments of this invention are manufactured according to the methods of this invention.

### BRIEF DESCRIPTION OF THE DRAWINGS

The invention is better understood by reading the following detailed description with reference to the accompanying figures in which:

FIG. 1 is a schematic illustration of a resistor according to an embodiment of the current invention;

FIG. 2 is a schematic illustration of a capacitor according to an embodiment of the current invention;

FIG. 3 is a schematic illustration of a diode according to an embodiment of the current invention;

FIG. 4 is a schematic illustration of an inductor according to an embodiment of the current invention;

FIG. 5 is a side view of a bottom-gated transistor according to an embodiment of the current invention;

FIG. 6 is a side view of a top-gated transistor according to an embodiment of the current invention;

FIG. 7 is a top view of a side-gated transistor according to an embodiment of the current invention;

FIG. 8 is a side view of a liquid-gated transistor according to an embodiment of the current invention;

FIG. 9 is a schematic layout of a transistor architecture of the device made in accordance with Example 1;

FIG. 10 is an AFM image of the NT network which acts as the gate layer;

FIG. 11 is an optical image of the transistor;

FIG. 12 depicts the optical transmission versus wavelength of a typical device;

FIG. 13 depicts source-drain current at Vsd=500 mV versus drain voltage for three devices with different nanotube network densities in the conducting channel; and

FIG. 14 depicts the transistor characteristics upon bending almost 180° and after the bending force was removed.

### DETAILED DESCRIPTION

In describing embodiments of the present invention illustrated in the drawings, specific terminology is employed for the sake of clarity. However, the invention is not intended to be limited to the specific terminology so selected. It is to be understood that each specific element includes all technical equivalents which operate in a similar manner to accomplish a similar purpose.

Accordingly, the current invention is directed to electronic devices that have components made with nanowires and the manufacture of such electronic devices. The invention includes two-electrode devices, such as resistors, diodes, capacitors, and inductors. The invention also includes three-electrode devices, such as transistors. Furthermore, each device of the invention can be used in combination with more that one such device of this invention to provide circuits built from a plurality of such components. The invention includes such circuits. Devices according to embodiments of this invention can be made to have a high degree of transparency. However, the invention is not limited to only transparent devices.

In current transistor configurations the gate and also the source and drain are metal electrodes. While this is a manufacturable architecture, neither the gate and/or source/drain electrodes are flexible and/or transparent. In addition there is usually a large interface resistance between the electrodes and the carbon nanotube network. In addition, there is a need for a simple method of fabrication, where the different layers that form the transistors, and the fabrication of the different layers are compatible. The invention satisfies this need, and three components of the device are all formed from the same material.

Transistors in accordance with the present invention include the following four basic elements: a source, a drain, a gate and a conducting channel. As a feature of the present invention, at least one of these four basic elements besides the conducting channel comprise at least one nanowire, for example a carbon nanotube network. As further features of the present invention, two, three or all four of the basic elements can have at least one nanowire.

The fabrication may include pattering using methods such as shadow masking or optical lithography to fabricate devices with appropriate geometry.

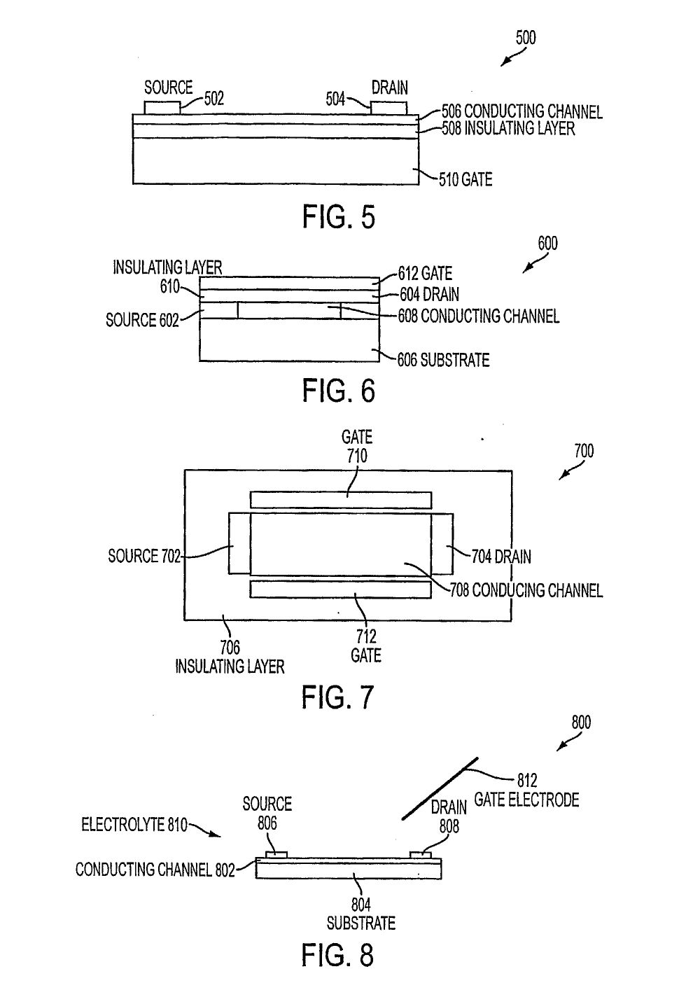

The following geometries, and transistor configurations are within the scope of the current invention:
1. A carbon nanotube transistor where a carbon nanotube network provides the source and drain, the conducting channel and the gate electrode, together with the fabrication of such device. In this device, all four of the basic elements are made from carbon nanotube networks. The source and drain can be made with the same type of nanotube network for certain advantages in cost and manufacturing, however, this is not required and there may be situations where it is desirable to provide a source and drain which are made from different nanotube networks.
2. Examples of embodiments of the device:
   Carbon nanotube network used for the source and drain; and a carbon nanotube network used for the conducting channel.
   Carbon nanotube network used for the source and drain; and a carbon nanotube network used for the gate.
   Carbon nanotube network used for the gate; and a carbon nanotube network used for the conducting channel.
3. Different geometries
   Bottom gating as described in FIG. 5.
   top gating as described in FIG. 6.
   “side gating” as described in FIG. 7.
   liquid gating as described in FIG. 8
4. The nanotube networks can be formed as part of a composite, such as described in PCT US04/43179.
5. The nanotubes used to make the networks can be pristine or doped for p- and n-type transistors.
6. Networks with two different species may be used (nanotubes and polyaniline for example) to provide different conducting properties.
7. Networks with different densities at different locations on the substrate may be used.
8. Networks can be patterned on the surface to provide some areas that are covered some areas that are not covered.
9. Networks may be used that are close to the percolation threshold, as defined in L. Hu, D.S. Hecht and G. Grüner. Percolation in Transparent and Conducting Carbon Nanotube Networks. Nano Lett. 4, 2523 (2004).
10. A network density that is not more than 5 times larger than the density corresponding to the percolation threshold density has been found to provide good results.
11. Networks may be used where the density of the network corresponds to less than full surface coverage.
12. The substrates for the transistor may be:
   Transparent;
   Have more than 90% transparency in the visible spectral range; and
   Flexible
13. The present invention is intended to cover not only transistors, but other active electronic devices, such as resistors, diodes, capacitors and inductors.

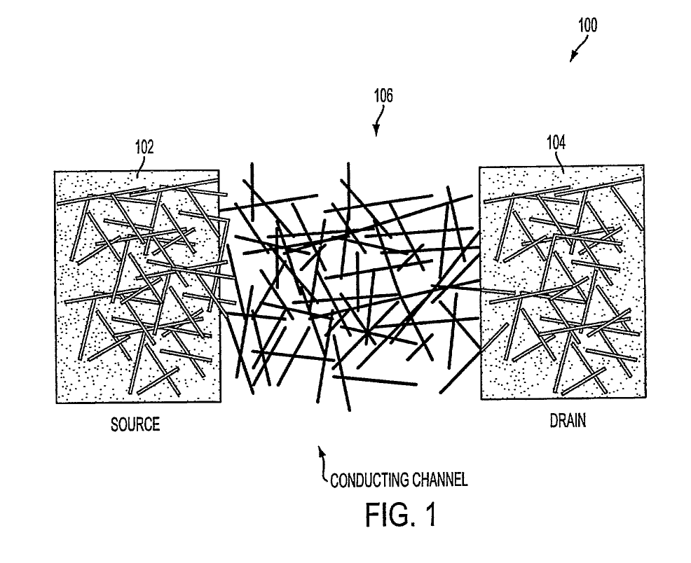

FIG. 1 is a schematic illustration of a resistor 100, which is a two-electrode device, according to an embodiment of this invention. Generally, the resistor 100 has a source electrode 102 and a drain electrode 104 spaced apart from the source electrode 102. There is a conducting channel 106 disposed between the source electrode 102 and the drain electrode 104. At least one of the source electrode 102 and drain electrode 104 comprises at least one nanowire. The source electrode 102 and/or drain electrode 104 may comprise a network of nanowires in some embodiments of the current invention. The source electrode 102 and drain electrode 104 may be constructed to be similar or essentially the same structures for ease of manufacture and/or economy. However, the invention is not limited to only such embodiments. The conducting channel 106 may also comprise a nanowire or a network of nanowires, as is illustrated in the example of FIG. 1. However, this invention is not limited to only the example illustrated in FIG. 1 and may include cases in which the conducting channel is not in a network of nanowires, or does not include any nanowires. In general, the conducting channel 106 may be constructed of any conducting material that suits the purpose for the particular application. The source electrode 102, drain electrode 104 and conducting channel 106 may be deposited on a substrate, such as in the plane of the paper of FIG. 1. Any one, two or three of the source electrode 102, drain electrode 104 or conducting channel 106 may be independent network of nanowires or may be a composite material in which the nanowires are formed within a surrounding material. A surrounding material may be selected from polymers, for example, or other materials depending on the particular application.

Carbon nanotubes are considered to be one particular type of nanowire according to the current invention. However, this invention is not limited to only carbon nanotubes for the nanowires. The term nanowire is meant to have a broad definition, as follows.

Nanowires, or molecular nanowires are defined as having dimensions less than 500 nm in diameter (the diameter is the average of the cross-sectional width) and have an aspect ratio exceeding 10 (e.g. a 100 nm diameter nanowire must have a length that is equal to or greater than 1 micron). The term “molecular nanowire”, is used herein interchangeably with “molecular nanofibers” and it is intended that when the term “molecular nanowire” is used alone, it is intended to include molecular nanofibers. A network of molecular nanofibers can be made from a variety of known molecular semiconductor nanowires. Set forth below is a listing of known examples of molecular nanowire materials that can be used to make networks of molecular nanowires in accordance with the present invention.

Single element nanowires made from silicon using known procedures may be used to form a nanowire network. Procedures for making such nanowires are set forth in detail in Refs. 1-21. (These references are listed at the end in an appendix. They are a part of the disclosure and are incorporated by references as also indicated above.) Single element nanowires made from germanium may also be used. Details of synthesis are set forth in Refs. 9, 17 and 22-27. Other examples of single element nanowires include selenium and tellurium nanowires, which are made according to known procedures as set forth in Refs. 28-29 and Ref. 30, respectively.

Nanowires made from a combination of Group III-V materials using known procedures may be used to form the network. Examples of Group III-V materials that can be used to form nanowire networks include Ga, In, N, P, As and Sb. Details of examples of synthesis procedures for these nanowires are set forth as follows: GaN (Refs. 8, 31-45); GaP (Refs. 39, 46 and 47); GaAs (Refs. 42 and 48-50); InN (Ref. 51); InP (Refs. 8, 38 and 52-54); and InAs (Ref. 55).

Nanowires made from a combination of Group II-VI materials using known procedures may also be used to form the network. Examples of group II-VI materials that can be used to form nanowire networks include Zn, Cd, Hg, S, Se and Te. Details of examples of synthesis procedures for these nanowires are set forth as follows: ZnS (Refs. 56-60); ZnSe (Refs. 44, 59 and 60); CdS (Refs. 59-72); CdSe (Refs. 59, 60, 65, 68, 69, 71 and 73); CdTe (Refs. 65, 73 and 74); and HgS (Ref. 75).

Nanowires made from metal oxides using known procedures may be used to form the network. Examples of metal oxide nanowires and references to the details for making them are as follows; CdO (Refs. 76-78); Ga2O3 (Refs. 79-88); In2O3 (Refs. 85 and 89-99); MnO (Refs. 100-102); NiO (Ref. 103); PbO (Ref. 104); Sb2O3 (Ref. 25); SnO2 (94 and 105-112); and ZnO (Refs. 113-117).

Nanowires made from metal chalcogenides using known procedure may be used to form the network. Examples of metal chalcogenides that can be used to make nanowires include Mn, Fe, Co, Ni, Cu, Ag, Sn, Pb and Bi. Examples of metal chalcogenide nanowires and references to the details for making them are as follows: AgxMy (Refs. 29 and 118-124); BixMy (Refs. 125-134, 135 and 136-137); CoxMy (Ref. 138); CuxMy (Refs. 139 and140); MnM (Ref. 141); NiM2 (Ref. 142); PbM (Refs. 114 and 143-152); and SnM (Refs. 153 and 154). M is Se, S or Te.

Nanowires made from ternary chalcogenides using known procedures may also be used to form the network. Examples of ternary chalcogenide nanowires and references to the details for making them are as follows: CuInM (Ref. 155); AgSnM (Ref. 156); CdMnM (Ref. 141); and CdZnM (Ref. 157) where M also can be Se, S or Te.

Nanowires (also referred to as nanofibers) made from conducting polymers may be used to form the network. Examples of conducting polymer nanowires and references to the details for making them are as follows: polyaniline (Refs. 82 and 158-167); polypyrrole (Refs. 158, 160 and 168-170); and polythiophene (Refs. 158, 169 and 171-173).

Nanowires of metals and alloys may be made using a variety of techniques.

They include:

Aluminum-Silicon Alloy

Paulose, M.; Grimes, C.; Varghese, O.; Dickey, E. “Self-assembled fabrication of aluminum-silicon nanowire networks.” Applied Physics Letters, Vol. 81, No. 1, 2002.

Gold Nanowire Networks

O'shea, J.; Phillips, M.; Taylor, M.; Moriarty, P.; Brust, M.; Dhanak, V. “Colloidal particle foams: Templates for Au nanowire networks?” Applied Physics Letters, Vol. 81, No. 26, 2002.

Indium Oxide (In2O3)

Lao, J.; Huang, J.; Wang, D.; Ren, Z. “Self-Assembled In203 Nanocrystal Chains and Nanowire Networks.” Advanced Materials, Vol. 16, No. 1, 2004.

Copper Nanowires

Adelung, R. et.al. “Self-Assembled Nanowire Networks by Deposition of Copper onto Layered-Crystal Surfaces.” Advanced Materials, Vol. 14, No. 15, 2002.

Components of the resistor 100 may be constructed from any one or combination of a variety of methods. For example, components of the resistor 100 may be made using printing and/or spraying methods. Both the printing and spraying methods of SWNT film deposition can be patterned. To pattern with a spray technique, standard optical lithography techniques can be used to pattern photoresist on an appropriate substrate, and the SWNTs can be sprayed over the photoresist. Washing away the photoresist yields a patterned SWNT sample. This can be patterned down to 1 μm resolution. To pattern with the printing technique, one can first pattern the PDMS stamp by again using optical lithographic techniques to pattern photoresist on an appropriate substrate and then filling over that with PDMS. The patterned stamp will now yield a patterned nanotube film when printed. The resolution of this is limited by the flexibility of the PDMS stamp, but at least 10 μm can be obtained.

Other manufacturing techniques that may be employed to produce components of the resistor 100 may include the following:

### Deposition Methods

Deposition methods that can be used to form nanowire networks on substrates include the following:

### 1. Solution Casting:

A great variety of nanowires can be made in solution and cast onto a substrate. See Refs. 28, 29, 50, 64, 68, 75, 96, 126, 131, 140, 143, 153 and 174-194 for details of examples of procedures that may be used to make solutions of nanowires. These nanowires can be readily deposited onto an FET device by drop casting. Upon drying the solvent, network structures form. For example, we deposited a polyaniline nanowire network on a silicon wafer cast from a water dispersion using the procedure described in detail in Ref. 164.

### 2. Langmuir-Blodgett Techniques:

Nanowires self-assemble into interconnecting networks when organic solvents containing nanowires are spread onto a water surface. The network can then be transferred from the water surface to a solid substrate by Langmuir-Blodgett techniques. Details of such procedures are set forth in Refs. 195-197.

### 3. Direct Growth of Nanowires by Chemical Vapor Deposition (CVD):

Using chemical vapor deposition, some nanowires can be directly grown as networks on substrates. Details of an example of CVD procedure for forming a network of nanowires as set forth in Ref. 198.

### 4. Electrospinning.

In a similar fashion to spider web networks, electrospining has been demonstrated to form networks of polymer nanowires/fibers on solid substrates (see Refs. 199 and 200). In a typical process, a polymeric melt or solution is extruded from the orifice of a needle to form a small droplet. In the presence of a strong electric field, charges built up on the surface of the droplet will overcome the surface tension to induce the formation of a liquid jet that is subsequently accelerated toward a grounded target. As the solvent is evaporating, this liquid jet is stretched to many times its original length to produce nanofibers (nanowires) of the polymer. The nanofibers are collected as inter-weaving networks on spinning target.

In accordance to the current invention, the resistor 100 may be constructed on a transparent substrate and may itself be transparent to a sufficient degree to be useful in a variety of electro-optic applications in which it is desirable to have transparent electronic components. In one example, one may manufacture the combination of source electrode 102, drain electrode 104 and conducting channel 106 to have nanowire networks to provide a desired resistance. For example, source electrode 102 and drain electrode 104 may be constructed to be similar to each other, while conducting channel 106 may be constructed to have a nanowire network which differs from source electrode 102 and drain electrode 104. The resistor 100 may be formed on a substrate, for example.

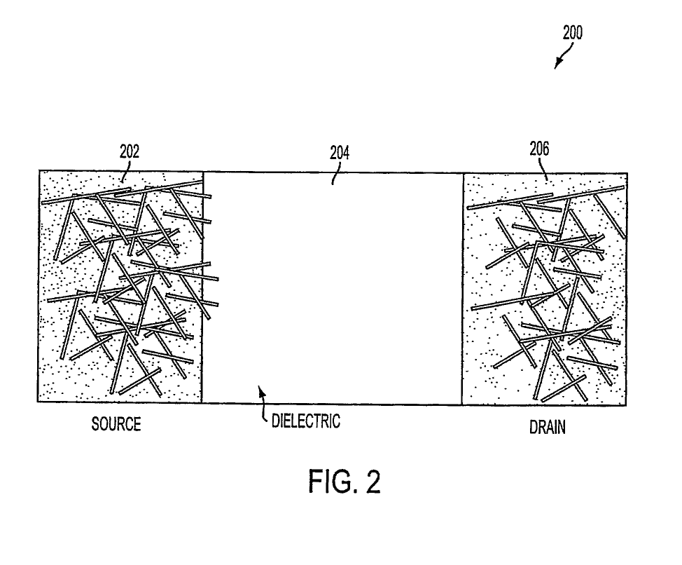

FIG. 2 is a schematic illustration of a capacitor 200 according to an embodiment of the current invention. The capacitor 200 has a source electrode 202 and a drain electrode 204 with a dielectric material 206 disposed therebetween. The terms “source electrode” and “drain electrode” are used in a broad sense in this specification. For example, there typically will not be current flowing between the source electrode 202 and drain electrode 204 in the capacitor 200 until the breakdown voltage is reached. Such electrodes are nonetheless included within the definition of source electrode and drain electrode in the specification. Either one or both of the source electrode 202 and drain electrode 204 may be constructed from nanowires as described in reference to resistor 100. One may select a material for the dielectric 206 from suitable available dielectric materials according to the desired application. The capacitor 200 may be formed on a substrate in substantially a two-dimensional structure, or may be formed in a bulk structure to form a three-dimensional capacitor.

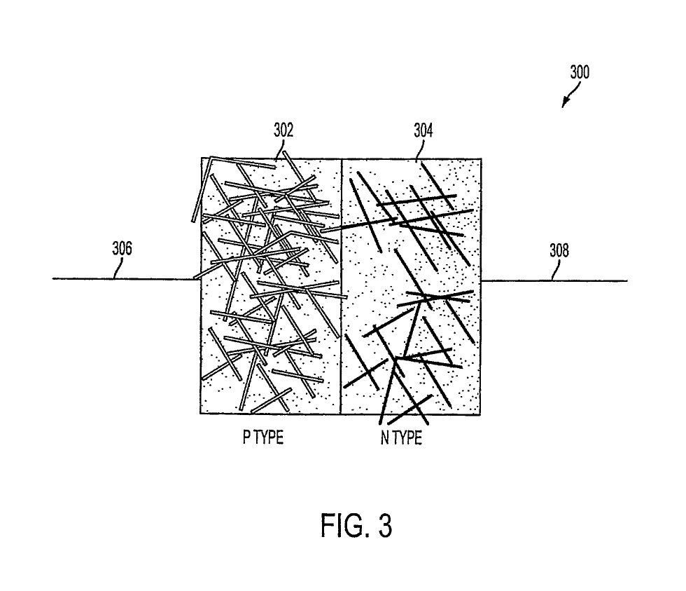

FIG. 3 illustrates an example of a diode 300 according to an embodiment of this invention. The diode 300 has a p-type section 302 and an n-type section 304 connected to conducting leads 306 and 308, respectively. The term source electrode and drain electrode in the current application is intended to have a broad meaning which can be identified with the leads 306 and 308, or can include portions of the p-type structure 302 and n-type section 304. In either case, there will be a semiconductor region between the source electrode and the drain electrode, for example which may include the p-n junction of the semiconductor. The p-type structure 302 comprises p-type semiconductor material, and the n-type structure 304 comprises n-type semiconductor material. At least one of the p-type structure 302 and n-type structure 304 comprises semiconductor nanowires of the corresponding p- or n-type, respectively. In some embodiments, both the structures 302 and 304 may comprise nanowires. The diode 300 may be formed on a substrate, for example.

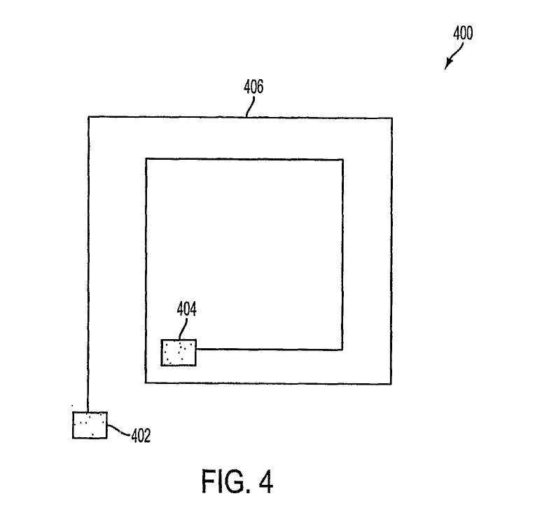

FIG. 4 is a schematic illustration of an example of an inductor 400 according to an embodiment of the current invention. The inductor 400 has a source electrode 402 and a drain electrode 404 connected by a conducting path 406. The conducting path 406 is shown with sharp corners in this example, but it may include curved paths as well. Furthermore, the conductive path 406 is not limited to the number of loops illustrated in FIG. 4. One may select the number of both loops according to the desired application. At least one of the source electrode 402, drain electrode 404 and conducting path 406 comprises nanowires. Any one, two or three of the source electrode 402, drain electrode 404 and conducting path 406 may be constructed from nanowires by any one or combination of the methods described above in regard to the resistor 100. Inductor 400 may be formed on a substrate, for example.

FIG. 5 is a schematic illustration of a side view of a transistor 500 according to an embodiment of this invention. The transistor 500 is an example of a bottom-gated transistor. The transistor 500 has a source electrode 502, a drain electrode 504, and a conducting channel 506. The conducting channel 506 is disposed on insulating layer 508 and gate electrode 510. The conducting channel 506 may comprise nanowires, but the invention is not limited to only that case. In addition, at least one of the source electrode 502, drain electrode 504 and gate electrode 510 comprises nanowires. Any combination of one, two, three or four of the source electrode 502, drain electrode 504, conducting channel 506 and gate electrode 510 may comprise nanowires. The source electrode 502, drain electrode 504, conducting channel 506 and/or gate electrode 510 may be constructed by any one or combination of methods described above in regard to the resistor 100.

FIG. 6 is a schematic illustration of a transistor 600 according to another embodiment of the current invention. The transistor 600 is an example of a top-gated transistor. Source electrode 602 and drain electrode 604 are formed on substrate 606. A conducting channel 608 is formed on substrate 606 between source channel 602 and drain channel 604. An insulating layer 610 is formed on the combined structure of the source electrode 602, conducting channel 608 and drain electrode 604. The conducting channel 608 may comprise nanowires, but this invention is not limited to only that case. At least one of the source electrode 602, drain electrode 604 and gate electrode 612 comprises one or more nanowires. Any one or combination of the source electrode 602, drain electrode 604, gate electrode 612 and conducting channel 608 may be constructed by any one or combination of the methods described above in regard to the resistor 100.

FIG. 7 is a schematic illustration of a transistor 700 according to another embodiment of this invention. The transistor 700 is an example of a side-gated transistor 700 according to the current invention. The transistor 700 has a source electrode 702 and a drain electrode 704 spaced apart from the source electrode 702, and formed on insulating layer 706. A conducting channel 708 is formed on the insulating layer 706 between the source electrode 702 and the drain electrode 704. The transistor 700 has a first gate electrode 710 and a second gate electrode 712 formed on the insulating layer 706 spaced apart from the conducting channel 708 therebetween. The conducting channel 708 may comprise one or more nanowires, but this invention is not limited to only that case. In addition, at least one of the source electrode 702, drain electrode 704, first gate electrode 710 and second gate electrode 712 comprises nanowires. Any one or combination of the source electrode 702, drain electrode 704, conducting channel 708, and gate electrodes 710, 712 may comprise nanowires and may be constructed according to any one or combination of the methods described above in regard to the resistor 100.

FIG. 8 is a schematic illustration of another embodiment of a transistor 800 according to the current invention. The transistor 800 is an example of a liquid-gated transistor according to an embodiment of the current invention. The transistor 800 has a conducting channel 802 formed on substrate 804. A source electrode 806 and a drain electrode 808 are formed on conducting channel 802 with a space reserved therebetween. A liquid drop of electrolyte 810 is disposed on the source electrode 806, drain electrode 808 and conducting channel 802. A gate electrode 812 is in electrical contact with the electrolyte 810. In some embodiments of this invention, the gate electrode 812 may be a nanowire, or plurality of nanowires. However, the invention is not limited to only that case. The conducting channel 802 may comprise nanowires, but the invention is not limited to that particular case. At least one of the source electrode 806, drain electrode 808 and gate electrode 812 comprises nanowires. Any one or combination of the source electrode 806, the drain electrode 806 and the conducting channel 802 may comprise one or more nanowires and may be constructed according to any of the methods described above in regard to the resistor 100.

In the liquid gating configuration, the source, drain and conducting channel are connected in a similar manner as other transistor configurations. These components are immersed into an electrolyte along with an electrode. When a voltage is applied to this electrode, it changes the potential of the electrolyte and gates the conducting channel in a manner similar to a traditional transistor. There does not need to be an insulating layer in between the conducting channel and the electrolyte (although there may be) because the interface between the conducting channel and the electrolyte forms a capacitor, thus enabling the conducting channel to be gated.

There may also be a liquid capacitor configuration. In this case, the conducting channel serves as one plate of the capacitor, while the gating electrode and the electrolyte serve as the second plate of the capacitor. It should be noted that just as for traditional transistors and capacitors, any or all of the listed components can be made of nanowires. There has been considerable research into using carbon nanotube bundles as micro electrodes for liquid gating purposes.

Devices according to the current invention, including but not limited to any of the above embodiments, may be very flexible and/or highly transparent as compared to conventional devices. Actual devices may contain a plurality of devices according to the current invention forming various electrical circuits. Materials suitable for the current invention, and methods of manufacture, permit low cost and ease of manufacture according to some embodiments of this invention. Following are a couple of more specific examples according to the current invention. The invention is not limited to only those examples.

### EXAMPLES

### Example 1

### Bottom Gated Transistor with Nanotube Network Gate and Conducting Channel

A simple spray technology is used to fabricate transparent and highly flexible FETs, in which carbon nanotube networks of different densities deposited on the two sides of a transparent polymer act as the gate and as the conducting channel. The device mobility exceeds that of organic transistors, and the on/off ratio, while adequate, can be improved with optimization. The transparency in the visible range is independent of the operation and no decrease in performance has been found upon bending the device. The simple device architecture together with the ease of fabrication may have a significant impact on the field of plastic electronics.

### Device Fabrication

The devices were prepared on a plastic sheet of polyethylene terephthalate (PET). Unfunctionalized nanotubes are hydrophobic, and thus they stick well to the hydrophobic surface of the PET. The PET sheets we used were simple transparency sheets, although any plastic with a similar surface hydrophobicity can be used as the substrate. For example other suitable substrates include polyethylene, polycarbonate and polystyrene.

To form the gate layer of the FET, a suspension of SWNT was sprayed onto the PET substrate forming a dense nanotube network. The suspension was made from purified HipCo tubes from Rice, in a concentration of 1 mg/mL in a 1% solution of SDS. The suspension was sonicated using a probe sonicator and then centrifuged. The suspension was sprayed onto the PET substrate while the substrate was heated to 100° C. Heating the substrate prevents droplets from forming on the surface, thus inhibiting flocculation of the nanotubes. After several layers of NT are sprayed onto the PET, the substrate is rinsed in distilled water to remove the SDS. Thin strips of gold were evaporated at opposite edges of the substrate on top of the NT network and silver paint was used to connect the gold strips to the back of the substrate. This way, the gate could be contacted through the back of the device.

The insulating layer in our devices consisted of a 1.5 μm layer of Parylene N, evaporated directly onto the dense NT layer. Although there are transparent and flexible dielectrics that have better insulating properties, Parylene N forms a pin-hole free layer and thus insulates well despite the uneven surface of the dense NT network. Other examples of flexible and transparent dielectrics that may be used include polymethyl methacrylate and very thin layers of inorganic oxides.

A suspension of NT in 1% SDS at a concentration of 0.35 mg/mL was used to deposit the NT network for the source-drain channel. To get a thin, homogenous network for the source-drain channel, the NT were adsorbed onto the parylene. A single drop of the suspension is placed on the parylene, and then blown off using an air gun. The device is then rinsed in water to remove the SDS. This process is repeated drop by drop until the desired source-drain channel network is reached. Gold contacts are then evaporated onto the NT network to form the source and the drain. The devices had a channel ratio W/L of approximately 1.2.

The transmittance of the devices was measured using a Beckman Coulter DU 640 Spectrophotometer. At 550 nm, the transparency of the entire device was found to be 70%. Because a different, more transparent plastic substrate may be used, it is interesting to consider the transmittance of the active components of the device. Dividing out the substrate yields a transparency of the gate, insulating layer, and source-drain channel of 80%.

Transistor characteristics were measured using a Keithley 2400 sweeping the gate voltage from +/−35 V at a rate of one sweep per 10 seconds. Comparing the transistor characteristics of two devices with NT networks of different densities in the source-drain channel reveals that a denser network channel leads to overall higher conduction, but a correspondingly lower on/off ratio.

### Example 2

### Top Gated Transistor

In this configuration a nanotube network together with source and gate electrodes are fabricated using the methods described above. An insulating layer is fabricated on top of the structure and finally a nanotube network gate is deposited. The insulating layer can include Parylene N, evaporated directly onto the dense NT layer. Other exemplary flexible and transparent dielectrics that may be used include PMMA, Y₂O₃, and barium zirconate titanate (BZT).

### Example 3

### A Side Gated Transistor

In this configuration the nanotube network channel together with the source and gate are fabricated as described above. Using an appropriate patterning technique (shadow masking, optical lithography, ink jet printing , etc) can be used to deposit the gate on the same side of the substrate, next to the conducting channel.

### Example 4

### Transistors Using Nanotube Networks for Two of the Three Components, and a Different Material for the Third Component

For a device in which nanotube networks make up the gate layer and the source and drain electrodes, a second material, one that is semiconducting, must be used in the conducting channel. Some high performance transparent semiconducting materials include organic materials such as pentacene, and inorganic oxides such as In—Ga—Zn—O. Organic semiconductors can be evaporated or spin-coated onto the insulating layer (or the source and drain electrodes, depending on which transistor configuration is being used). Inorganic oxides can be deposited by pulse laser deposition at room temperature.

If carbon nanotube networks are used as the conducting channel and source and drain electrodes, a second material is needed for the gate. This material must be transparent and suitably conducting. Indium Tin Oxide (ITO), a transparent conducting oxide, and poly(3,4-ethylenedioxythiophene) (PEDOT), a transparent conducting polymer are two examples. The ITO can be evaporated using a CVC 601 Sputtering System. Using standard machine parameters and at a pressure of 2×10⁻⁶ Torr, a homogenous layer of ITO can be deposited at room temperature onto any suitable transparent substrate such as glass or polyethylene (PET) or any other polymer. At 90% transparency, ITO has a sheet resistance of 50 Ω/sq. It is often difficult to get a smooth layer of ITO through evaporation, and so a thin layer of PEDOT can be spin-coated on top of the ITO, or a spin-coated layer of PEDOT by itself can be used as the gate layer.

The ease of this technique also allows for a top gating configuration. Source and drain electrodes made from nanotube networks can be sprayed onto a substrate using a shadow mask to form the correct geometry. Next, a rare nanotube network can be spin coated or incubated onto and between the electrodes. Onto this nanotube network, Parylene can be evaporated, or another insulating polymer deposited. And then finally, to form the gate layer, ITO can be evaporated or PEDOT can be spin-coated to complete the device.

The final permutation, using carbon nanotube networks for the gate and the conducting channel, would also require a transparent and conducting material to serve as the source and drain electrodes. ITO could again be used for these electrodes. A shadow mask with an appropriate geometry would be placed either onto the substrate for a top gating configuration, or onto the conducting channel for a bottom gating configuration, and then ITO is simply evaporated.

### Example 5

### Transistors Using Nanotube Networks for All Three Components

The fabrication process for an all carbon nanotube transistor follows the same general procedure explained earlier. Although the description of the fabrication process described below describes fabricating an all carbon nanotube transistor in the standard bottom gating configuration, the process can be applied to all of the different device architectures. The only two components needed for the device are a suspension of carbon nanotubes and an insulating polymer.

The suspension of carbon nanotubes is sonicated to break up large bundles, and then centrifuged to remove any remaining bundles. The suspension is then sprayed directly onto the substrate to form a dense nanotube network which will function as the gate. Onto this network, an insulating polymer is deposited. Possible polymer deposition techniques include vapor phase polymerization (Parylene C, N), spin coating (PMMA) or electropolymerization (PmPV). The insulating layer thickness can be adjusted to obtain desired device performance characteristics. For the source-drain channel of the device, a rare network of nanotubes is adsorbed directly onto the insulating polymer.

Finally, using a shadow mask, two dense nanotube networks that act as source and drain are sprayed onto the source-drain channel network. The shadow mask designed with an appropriate source and drain electrode geometry is simply placed on top of the device, and then the suspension of nanotubes is applied through spraying. Current technology allows the fabrication of shadow masks which have a resolution down to 20 μm, and so these source and drain contacts can also have this resolution. The networks comprising the source and drain electrodes should be at least several monolayers thick to ensure adequate differentiation between these functioning electrodes and the rare network acting as the conducting channel and thus ensure a well-defined source-drain channel. Even at several monolayers thickness, these networks will still be around 85% transparent. The precise density of the source and drain networks can be optimized.

To connect to these source and drain electrode networks, standard techniques can be applied. Using a probe station, one can contact the probes directly to the source and drain electrode networks just as one would contact the probes to gold pads on a Si chip. In the case that the device is packaged into a chip carrier, the source and drain network electrodes could have microscopic wires attached through standard wire bonding methods.

### Example 6

### Transistors Using Nanotube Networks for One Component, and Different Materials for the Second and Third Component

Transistors can also be fabricated using the nanotube network as the source and drain, and using other flexible and transparent materials as the gate and the conducting channel. The fabrication routes would follow the routes that are described under 1. above. Configurations where the conducting channel is the nanotube network and the source and drain together with the gate is the other material or materials. Finally, nanotube networks could be used as the gate material.

### Further Details of Examples of Bottom Gated Transistors

The following example describes the fabrication of transparent and flexible transistors where both the bottom gate and the conducting channel are carbon nanotube networks of different densities, and Parylene N is the gate insulator. Device mobilities of 1 cm²V⁻¹ s⁻¹ and on/off ratios of 100 are obtained, with the latter influenced by the properties of the insulating layer. Repetitive bending has minor influence on the characteristics, with full recovery after repeated bending. The operation is insensitive to visible light and the gating does not influence the transmission in the visible spectral range.

The quest for flexible and transparent transistors has recently resulted in several noteworthy achievements. Transparent transistors have been fabricated using both polymers (Stutzman, N.; Friend, R. H.; Sirringhaus, H. Science. 2003, 299, 1881; Dimitrakopoulos, C. D.; Purushotharnan, S.; Kymissis, J.; Callegari, A.; Shaw, J. M. Science. 1999, 283, 822; Dimitrakopoluos, C. D.; Malefant, P. R. L. Adv. Mater. 2002, 14, 99) and inorganic oxides (Nomura, K.; Ohta, H.; Takagi, A.; Kamiya, T.; Hirano, M.; Hosono, H. Nature, 2003, 432, 488; Nomura, K. ; Ohta, H.; Ueda, K.; Katniya, T.; Hirano, M.; Hosono, H. Science 2003, 300, 1269) These advances, notable in the emerging technology arena that is generally called “plastic electronics,” have received wide publicity. Both, nevertheless, have significant deficiencies. The former have low mobility and the latter do not have the desired flexibility and are not easily manufacturable. These factors severely limit the application potential of the devices. Our method introduces a transistor architecture that has the potential to include only two materials: carbon nanotubes (NTs) and a polymeric gate insulator. This simplicity of structure would ensure a simple manufacturing process.

Carbon nanotubes, because of their excellent electronic properties, have been explored for applications as active electronic devices. Field Effect Transistors (FETs) with NT conducting channels have been fabricated (Martel, R.; Schmidt, T.; Shea, H. R.; Hertel, T.; Avouris Ph. Appl. Phys. Lett. 1998, 73, 2447; Tans, S. J.; Verschueren, A. R. M.; Dekker, C. Nature 1998, 393, 49), and their properties and operation explored (Javey, A.; Guo, J.; Wang, Q.; Lundstrom, M.; Dai, H. Nature 2003, 424, 654; Durkop, T.; Getty, S. A.; Cobas, E.; Fuhrer, M. S. Nano Lett. 2004, 4, 35; Bradley, K.; Gabriel, J.-C. P.; Star, A.; Grüner, G. Appl. Phys. Lett. 2003, 83, 3821). Subsequently it has been shown (Gabriel, J.-C. P. Large Scale Production of Carbon Nanotube Transistors: A Generic Platform for Chemical Sensors. MRS Proceedings Volume 776, Q12.7; Snow, E. S.; Novak, J. P.; Campbell, P. M.; Park, D. Appl. Phys. Lett. 2003, 82, 2145) that a random network of nanotubes with an appropriate density can also act as a conducting channel in a FET configuration. This has opened up the avenue for a manufacturable device architecture. Room-temperature fabrication techniques enabling flexible transistors (Bradley, K.; Gabriel, J.-C. P.; Gruner, G. Nano Lett. 2003, 3, 1353) have been also explored. It has been shown that due to the high mobility of carbon nanotubes, a network with low sheet resistance is also transparent in the visible spectral range (Wu, Z.; Chen, Z.; Du, X.; Logan, J. M.; Sippel, J.; Nikolou, M.; Kamaras, K.; Reynolds, J. R.; Tanner, D. B.; Hebard, A. F.; Rinzler, A. G. Science 2004, 305, 1273; Hu, L.; Hecht, D. S.; Grüner, G. Nano Lett. 2004, 4, 2523). We have fabricated, using an extremely simple spray technology, field effect transistors where carbon nanotube networks of different densities provide both the gate and the conducting channel. We find that the devices are highly transparent, that the mobility is superior to that of organic transistors, and that repeated bending does not lead to a substantial effect on the transistor characteristics. The transistor architecture, aside from having a possible impact on a new technology, represents a further step in the advancement of carbon nanotube based transistors.

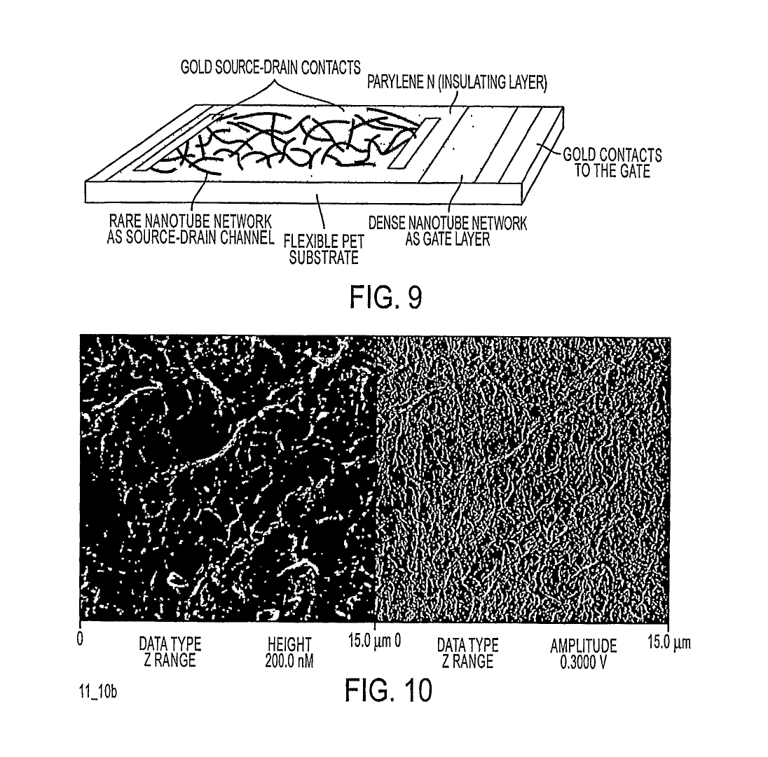

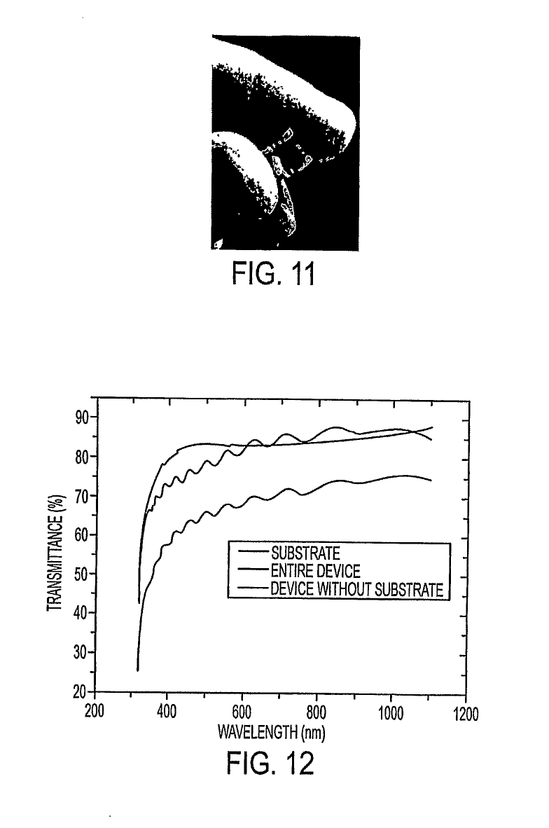

A schematic illustration of the FET devices that have been fabricated is shown in FIG. 9 together with an optical image of one of the transistors. The devices were prepared on a sheet of polyethylene (PET), using purified, single walled HpCO nanotubes from CNI (used as received). Because nanotubes are hydrophobic, they stick well to the hydrophobic surface of the PET. The PET sheets used were simple plastic sheets normally used as transparency slides, although any plastic with a similar surface hydrophobicity can be used as the substrate. To form the gate layer of the FET, a suspension of SWNTs was sprayed onto the PET substrate forming a dense nanotube network (Kaempgen, M.; Duesberg, G. S.; Roth, S. accepted in App. Surf. Sci. 2005). The suspension consisted of a concentration of 1 mg/mL of nanotubes in a 1% solution of aqueous sodium dodecyl sulfate (SDS). The suspension was sonicated for one hour at 40 W using a probe sonicator and then centrifuged at 14000 rpm for 20 minutes. After centrifugation, the suspension was decanted so that only the supernatant of the centrifuged material was included in the final suspension. Centrifuging and decanting removes large, heavier bundles from the suspension. The suspension was then sprayed onto the PET substrate while the substrate was heated to 100° Celsius. Heating the substrate prevents droplets from forming on the surface, thus inhibiting flocculation of the nanotubes. After several layers of NT are sprayed onto the PET, the substrate is rinsed in distilled water to remove the SDS. Thin strips of gold were evaporated at opposite edges of the substrate on top of the NT network and silver paint was used to connect the gold strips to the back of the substrate. This way, the gate could be contacted through the back of the device.

The insulating layer in our devices consisted of a 1.5 μm thick layer of Parylene N, evaporated directly onto the dense NT layer. Although there are transparent and flexible dielectrics that have better insulating properties, Parylene N forms a pin-hole free layer and thus insulates well despite the uneven surface of the dense NT network. Parylene can also be deposited at room temperature, ensuring that the PET substrate will not be damaged in the gate deposition process. Accordingly, Parylene is a suitable dielectric.

A similarly prepared suspension of NT in 1% SDS at a concentration of 0.35 mg/ml was used to deposit the NT network for the source-drain channel. To get a thin, homogenous network for the source-drain channel, the NTs were adsorbed onto the parylene. A single drop of the suspension is placed on the parylene, and then blown off using an air gun. The device is then rinsed in water to remove the SDS. This process is repeated drop by drop until the desired source-drain channel network density is reached. Gold contacts are then evaporated onto the NT network to form the source and the drain. The devices had a channel ratio W/L of approximately 1.

AFM images (FIG. 10) show that the NT network in the gate layer consists mostly of bundles with an average diameter of 20 nm and fairly homogenous coverage. The average sheet resistance of the gate layer is 2.4 kΩ/sq, which corresponds to approximately 12 NT bundles/um² using the data from Hu et. al. Because the purpose of the gate layer is to apply an electric field, and not to pass current, it is not necessary to achieve a low sheet resistance in this layer. The source-drain channel network is comprised of similarly sized bundles, though it is much less dense (density around 1 NT bundle/um²) with sheet resistances ranging from 30 to 150 MΩ/sq.

The optical transmittance of the devices was measured using a Beckman Coulter DU 640 Spectrophotometer. The transistor characteristics were measured using a Keithley 2400 sweeping the gate voltage from +/−35 V at a rate of 14 V/s and a source-drain bias of 500 mV. Comparing the transistor characteristics of three devices with NT networks of different densities in the source-drain channel reveals that a denser network channel leads to overall higher conduction, but a correspondingly lower on/off ratio.

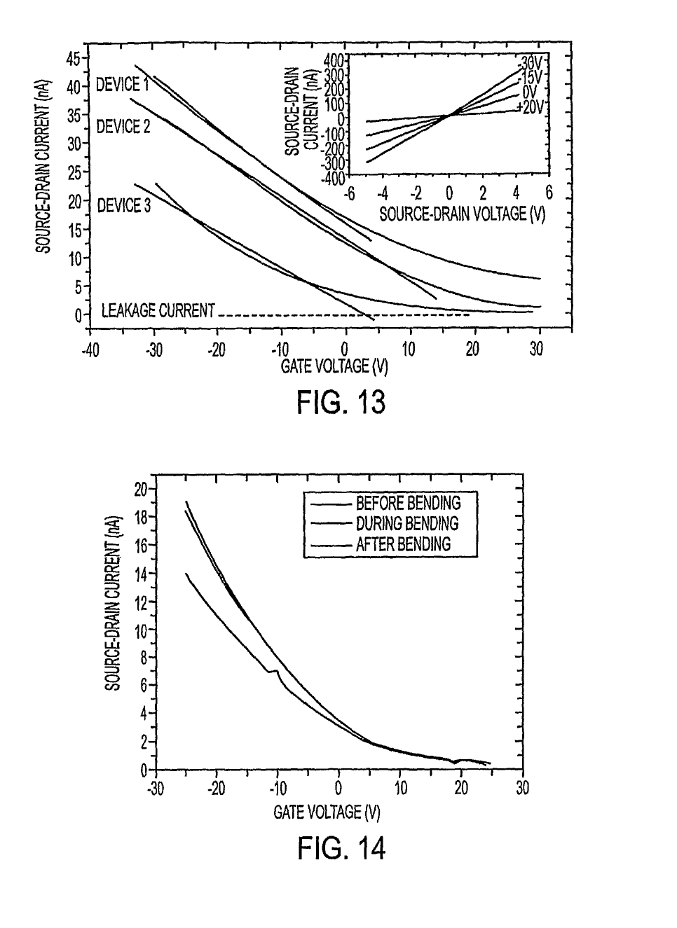

The optical transparency of a typical example of a device, shown in FIG. 12, is displayed in the visible to NIR spectral range. At 550 nm, the transparency of the entire device was found to be approximately 68%, weakly dependent on the wavelength. The interference pattern in the optical data is due to reflection within the Parylene layer, which is of the same order thickness as the wavelengths studied. Because a different, more transparent plastic substrate may be used in further embodiments, it is interesting to consider the transmittance of the active components of the device. Dividing out the substrate yields a transparency of the gate, insulating layer, and source-drain channel of 81%. Although this approach is not a fully consistent description of the optical properties of the system, which consists of three layers and may include internal reflection at the different material boundaries, it gives a good first order approximation of the transparency of the nanotube networks. Using this same approximation, we found the NT network acting as the gate to have a transparency of 85%, the Parylene layer to have a transparency of 95%, and the NT network in the source-drain channel to have a transparency of approximately 100%. The transistor characteristics of three examples of devices are displayed in FIG. 13. The three devices have identical gate networks, but networks of different densities in the source-drain channel. Device 1 has the densest network, with a sheet resistance of 30 MΩ/sq. Device 2 has a less dense network with a sheet resistance of 39 MΩ/sq, and Device 3 has the least dense network with a sheet resistance of 144 MΩ/sq. Plotted with each device characteristic is a fit to the linear portion of the data. The leakage current of a typical device is also shown, and this leakage current is roughly independent of the applied gate voltage.

Although the devices do not reach saturation in the “on” state, the on/off ratio for the applied voltage range can still be estimated. Device 3 has an on/off ratio of approximately 90. Device 2 has an en/off ratio around 70, while Device 1, with the densest NT network, has an on/off ratio around 7. It is expected that the device with the rarest NT network will have a higher on/off ratio because this device will have fewer all-metallic paths which remain conducting even when the device is in the “off” state. Furthermore, the leakage current through the dielectric is on the order of the “off” current in this device, and so using a better dielectric in order to decrease the leakage current could improve the on/off ratio even more. If we subtract out the leakage current from the off current, the on/off ratio for the rarest device improves to around 400.

Using a standard expression for mobility,

$$μ = \frac{l}{w} \frac{d {I}_{sd}}{d {V}_{g}} \frac{d}{k {ɛ}_{0}} \frac{1}{{V}_{d}} \qquad ( 1 )$$

the mobilities of the devices were estimated. In this expression, l represents the length of the channel (i.e., the distance between the source and the drain contacts), w is the width of the channel, d is the thickness of the dielectric layer, k is the dielectric constant of the dielectric, and V_{d} is the source-drain voltage bias at which the transfer characteristics were measured. To estimate

$$\frac{d {I}_{sd}}{d {V}_{g}} ,$$

we measured the slope of the I-V_{g} curve in the linear region. Though the slopes of the three plots appear similar in FIG. 13, the source-drain channel geometries were slightly different in the different devices, resulting in different estimated mobilities.

The device with the least dense NT network in the source-drain channel, Device 3, has an estimated mobility of 0.5 cm²V⁻¹ s⁻¹, Device 2 has an estimated mobility of 0.6 cm²V⁻¹ s⁻¹. The device with the more dense NT network, Device I, has an estimated mobility of 1 cm²V⁻¹ s⁻¹. It is understandable that the device with a more dense NT network would have a higher mobility (Y. Zhou, et al. p-Channel, n-Channel Thin Film Transistors and p-n Diodes Based on Single Wall Carbon Nanotube Networks. Nano Lett 4, 2031 (2004)) because in a dense NT network, there are more paths through which the electrons may travel.

To test the devices' flexibility, transistor characteristics measurements were taken before, during and after bending the device to a radial angle of 160°. FIG. 14 displays the results. Although the current is reduced slightly while the device is bent, the device recovers completely afterwards.

We have demonstrated a flexible and transparent transistor architecture where different components are fabricated using carbon nanotube networks. While certain parameters of the devices are comparable to transistors fabricated using room-temperature processes, significant improvements are expected with improved nanotube network characteristics. As is evident form FIG. 10, and also from the high sheet resistances, bundles of nanotubes—with current most likely flowing at the outer regions of the bundles—dominate the transport process. Better dispersion on the surface, together with improved starting material and a better dielectric, will lead to improved device performance, approaching those found in devices fabricated using chemical vapor deposition methods. The fabrication of the transistor architecture demonstrates the versatility of carbon nanotube networks transparent enough to allow applications in areas ranging from active matrix displays to smart windows. With source and drain potentially also fabricated using carbon nanotube networks, the architecture opens up the avenue towards simple electronic device fabrication, including potentially only two types of materials: carbon nanotubes and a polymeric insulating layer.

The embodiments illustrated and discussed in this specification are intended only to teach those skilled in the art the best way known to the inventors to make and use the invention. Nothing in this specification should be considered as limiting the scope of the present invention. The above-described embodiments of the invention may be modified or varied, and elements added or omitted, without departing from the invention, as appreciated by those skilled in the art in light of the above teachings. It is therefore to be understood that, within the scope of the claims and their equivalents, the invention may be practiced otherwise than as specifically described,

### Example of a Capacitor Device

Liquid capacitor devices use a configuration similar to that of the liquid-gated transistor. First, a suspension of carbon nano tubes is produced by sonicating a 0.1 mg/ml mixture of carbon nanotubes in 1% sodium dodecyl sulfide (SDS). The suspension is sonicated for 30 minutes in order to break apart the nanotubes which aggregate due to van der Waals forces. The suspension is then centrifuged at 1400 rpm for 30 minutes to remove the largest bundles from the suspension.

From this stock suspension, more dilute suspensions can be made in order to fabricate nanotube networks using a filtration method. Typically, 100-200 μl of the stock suspension is dispersed into 30 ml of 1% SDS. This suspension is then vacuum filtered onto an alumina filter, yielding a uniform network of small bundles of nanotubes.

This network is then transferred to a strip of PET using a PDMS stamp. Final sheet resistances of these networks is typically around 1 kΩ. A single silver electrode is then painted onto the plastic in order to contact the network. The silver electrode is completely passivated with a thin layer of PDMS.

Such devices can be used as a capacitor in a configuration similar to that of the liquid-gated transistor. This plastic device is inserted into a liquid buffer. A gate electrode is also inserted into the buffer and the entire configuration is the capacitor device. The nanotube network serves as one plate of the capacitor, the gating electrode serves as the other “plate” of the capacitor, and the double layer interface between the nanotube network and the liquid electrolyte serves as the dielectric layer of the capacitor. As the voltage applied to the electrode is changed, the capacitance between the gate electrode and the nanotube network changes, as one would expect for a typical capacitor device.

### REFERENCES

1. Banerjee, S., Dan, A. & Chakravorty, D. Synthesis of conducting nanowires. Journal of Materials Science 37, 4261-4271 (2002).

2. Barsotti, R. J. et al. Imaging, structural, and chemical analysis of silicon nanowires. Applied Physics Letters 81, 2866-2868 (2002).

3. Carim, A. H., Lew, K. K. & Redwing, J. M.

Bicrystalline silicon nanowires. Advanced Materials 13, 1489-+(2001).

4. Chung, S. W., Yu, J. Y. & Heath, J. R. Silicon nanowire devices. Applied Physics Letters 76, 2068-2070 (2000).

5. Cui, Y., Lauhon, L. J., Gudiksen, M. S., Wang, J. F. & Lieber, C. M. Diameter-controlled synthesis of single-crystal silicon nanowires. Applied Physics Letters 78, 2214-2216 (2001).

6. Gole, J. L., Stout, J. D., Rauch, W. L. & Wang, Z. L. Direct synthesis of silicon nanowires, silica nanospheres, and wire-like nanosphere agglomerates. Applied Physics Letters 76, 2346-2348 (2000).

7. Gu, Q., Dang, H. Y., Cao, J., Zhao, J. H. & Fan, S. S. Silicon nanowires grown on iron-patterned silicon substrates. Applied Physics Letters 76, 3020-3021 (2000).

8. Gudiksen, M. S., Lauhon, L. J., Wang, J., Smith, D. C. & Lieber, C. M. Growth of nanowire superlattice structures for nanoscale photonics and electronics. Nature 415, 617-620 (2002).

9. Hanrath, T. & Korgel, B. A. Supercritical fluid-liquid-solid (SFLS) synthesis of Si and Ge nanowires seeded by colloidal metal nanocrystals. Advanced Materials 15, 437-440 (2003).

10. Lew, K. K., Reuther, C., Carim, A. H., Redwing, J. M. & Martin, B. R. Template-directed vapor-liquid-solid growth of silicon nanowires. Journal of Vacuum Science & Technology B 20, 389-392 (2002).

11. Lew, K. K. & Redwing, J. M. Growth characteristics of silicon nanowires synthesized by vapor-liquid-solid growth in nanoporous alumina templates. Journal of Crystal Growth 254, 14-22 (2003).

12. Liu, Z. Q. et al. Synthesis of silicon nanowires using AuPd nanoparticles catalyst on silicon substrate. Journal of Physics and Chemistry of Solids 61, 1171-1174 (2000).

13. Morales, A. M. & Lieber, C. M. Rational synthesis of silicon nanowires. Abstracts of Papers of the American Chemical Society 213, 651-Inor (1997).

14. Shi, W. S. et al. Synthesis of large areas of highly oriented, very long silicon nanowires. Advanced Materials 12, 1343-1345 (2000).

15. Sunkara, M. K., Sharma, S., Miranda, R., Lian, G. & Dickey, E. C. Bulk synthesis of silicon nanowires using a low-temperature vapor-liquid-solid method. Applied Physics Letters 79, 1546-1548 (2001).

16. Zhang, Y. J. et al. A simple method to synthesize nanowires. Chemistry of Materials 14, 3564-3568 (2002).

17. Wu, Y. Y., Fan, R. & Yang, P. D. Block-by-block growth of single-crystalline Si/SiGe superlattice nanowires. Nano Letters 2, 83-86 (2002).

18. Yu, D. P. et al. Nanoscale silicon wires synthesized using simple physical evaporation. Applied Physics Letters 72, 3458-3460 (1998).

19. Yu, J. Y., Chung, S. W. & Heath, J. R. Silicon nanowires: Preparation, device fabrication, and transport properties. Journal of Physical Chemistry B 104, 11864-11870 (2000).

20. Yu, D. P. et al. Controlled growth of oriented amorphous silicon nanowires via a solid-liquid-solid (SLS) mechanism. Physics E 9, 305-309 (2001).

21. Zhang, Y. J. et al. Synthesis of thin Si whiskers (nanowires) using SiCl4. Journal of Crystal Growth 226, 185-191 (2001).

22. Coleman, N. R. B., Ryan, K. M., Spalding, T. R., Holmes, J. D. & Morris, M. A. The formation of dimensionally ordered germanium nanowires within mesoporous silica. Chemical Physics Letters 343, 1-6 (2001).

23. Morales, A. M. & Lieber, C. M. A laser ablation method for the synthesis of crystalline semiconductor nanowires. Science 279, 208-211 (1998).

24. Ryan, K. M., Erts, D., Olin, H., Morris, M. A. & Holmes, J. D. Three dimensional architectures of ultra-high density semiconducting nanowires deposited on chip. Journal of the American Chemical Society 125, 6284-6288 (2003).

25. Ye, C. H., Meng, G. W., Zhang, L. D., Wang, G. Z. & Wang, Y. H. A facile vapor-solid synthetic route to Sb₂O₃ fibrils and tubules. Chemical Physics Letters 363, 34-38 (2002).

26. Wu, Y. Y. & Yang, P. D. Germanium/carbon core-sheath nanostructures. Applied Physics Letters 77, 43-45 (2000).

27. Wu, Y. Y. & Yang, P. D. Germanium nanowire growth via simple vapor transport. Chemistry of Materials 12, 605-+ (2000).

28. Gates, B., Mayers, B., Cattle, B. & Xia, Y. N. Synthesis and characterization of uniform nanowires of trigonal selenium. Advanced Functional Materials 12, 219-227 (2002).

29. Gates, B. et al. Synthesis and characterization of crystalline Ag₂Se nanowires through a template-engaged reaction at room temperature. Advanced Functional Materials 12, 679-686 (2002).

30. Gates, B., Mayers, B., Grossman, A. & Xia, Y. N. A sonochemical approach to the synthesis of crystalline selenium nanowires in solutions and on solid supports. Advanced Materials 14, 1749-+ (2002).

31. Bae, S. Y., Seo, H. W., Park, J., Yang, H. & Song, S. A. Synthesis and structure of gallium nitride nanobelts. Chemical Physics Letters 365, 525-529 (2002).

32. Chang, K. W. & Wu, J. J. Low-temperature catalytic synthesis gallium nitride nanowires. Journal of Physical Chemistry B 106, 7796-7799 (2002).

33. Chen, X. L. et al. Straight and smooth GaN nanowires. Advanced Materials 12, 1432-1434 (2000).

34. Chen, C. C. & Yeh, C. C. Large-scale catalytic synthesis of crystalline gallium nitride nanowires. Advanced Materials 12, 738-+(2000).

35. Chen, C. C. et al. Catalytic growth and characterization of gallium nitride nanowires. Journal of the American Chemical Society 123, 2791-2798 (2001).

36. Cheng, G. S. et al. Large-scale synthesis of single crystalline gallium nitride nanowires. Applied Physics Letters 75, 2455-2457 (1999).

37. Cheng, G. S., Chen, S. H., Zhu, X. G., Mao, Y. Q. & Zhang, L. D. Highly ordered nanostructures of single crystalline GaN nanowires in anodic alumina membranes. Materials Science and Engineering a—Structural Materials Properties Microstructure and Processing 286, 165-168 (2000).

38. Gudiksen, M. S., Wang, J. F. & Lieiber, C. M. Synthetic control of the diameter and length of single crystal semiconductor nanowires. Journal of Physical Chemistry B 105, 4062-4064 (2001).

39. Lin, H. M. et al. Synthesis and characterization of core-shell GaP@GaN and GaN@GaP nanowires. Nano Letters 3, 537-541 (2003).

40. Lyu, S. C. et al. Catalytic synthesis and photoluminescence of gallium nitride nanowires. Chemical Physics Letters 367, 136-140 (2003).

41. Peng, H. Y. et al. Bulk-quantity GaN nanowires synthesized from hot filament chemical vapor deposition. Chemical Physics Letters 327, 263-270 (2000).

42. Shi, W. S., Zheng, Y. F., Wang, N., Lee, C. S. & Lee, S. T. A general synthetic route to III-V compound semiconductor nanowires. Advanced Materials 13, 591-+(2001).

43. Tang, C. C., Fan, S. S., Dang, H. Y., Li, P. & Liu, Y. M. Simple and high-yield method for synthesizing single-crystal GaN nanowires. Applied Physics Letters 77, 1961-1963 (2000).

44. Xiang, B. et al. Green-light-emitting ZnSe nanowires fabricated via vapor phase growth. Applied Physics Letters 82, 3330-3332 (2003).

45. Zhang, J. et al. Fabrication and photoluminescence of ordered GaN nanowire arrays. Journal of Chemical Physics 115, 5714-5717 (2001).

46. Lyu, S. C., Zhang, Y., Ruh, H., Lee, H. J. & Lee, C. J. Synthesis of high-purity GaP nanowires using a vapor deposition method. Chemical Physics Letters 367, 717-722 (2003).

47. Shi, W. S., Zheng, Y. F., Wang, N., Lee, C. S. & Lee, S. T. Synthesis and microstructure of gallium phosphide nanowires. Journal of Vacuum Science & Technology B 19, 1115-1118 (2001).

48. Shi, W. S., Zheng, Y. F., Wang, N., Lee, C. S. & Lee, S. T. Oxide-assisted growth and optical characterization of gallium-arsenide nanowires. Applied Physics Letters 78, 3304-3306 (2001).

49. Duan, X. F., Wang, J. F. & Lieber, C. M. Synthesis and optical properties of gallium arsenide nanowires. Applied Physics Letters 76, 1116-1118 (2000).

50. Yu, H. & Buhro, W. E. Solution-liquid-solid growth of soluble GaAs nanowires. Advanced Materials 15, 416-+ (2003).

51. Liang, C. H. et al. Selective-area growth of indium nitride nanowires on gold-patterned Si(100) substrates. Applied Physics Letters 81, 22-24 (2002).

52. Bakkers, E. P. A. M. & Verheijen, M. A. Synthesis of InP nanotubes. Journal of the American Chemical Society 125, 3440-3441 (2003).

53. Hogan, H. InP nanowires act as detectors. Photonics Spectra 36, 30-30 (2002).

54. Wang, J. F., Gudiksen, M. S., Duan, X. F., Cui, Y. & Lieber, C. M. Highly polarized photoluminescence and photodetection from single indium phosphide nanowires. Science 293, 1455-1457 (2001).

55. He, M. Q. et al. InAs nanowires and whiskers grown by reaction of indium with GaAs. Applied Physics Letters 82, 3749-3751 (2003).

56. Wu, Q. S., Zheng, N. W., Ding, Y. P. & Li, Y. D. Micelle-template inducing synthesis of winding ZnS nanowires. Inorganic Chemistry Communications 5, 671-673 (2002).

57. Wang, Y., Zhang, L., Liang, C., Wang, G. & Peng, X. Catalytic growth and photoluminescence properties of semiconductor single-crystal ZnS nanowires. Chemical Physics Letters 357, 314-318 (2002).

58. Li, Y., Wan, J. H. & Gu, Z. N. Synthesis of ZnS nanowires in liquid crystal systems. Molecular Crystals and Liquid Crystals 337, 193-196 (1999).

59. Duan, X. & Lieber, C. M. General synthesis of compound semiconductor nanowires. Advanced Materials (Weinheim, Germany) 12, 298-302 (2000).

60. Deng, Z. X., Li, L. B. & Li, Y. D. Novel inorganic-organic-layered structures: Crystallographic understanding of both phase and morphology formations of one-dimensional CdE (E=S, Se, Te) nanorods in ethylenediamine. Inorganic Chemistry 42, 2331-2341 (2003).

61. Cao, H. Q. et al. Sol-gel template synthesis of an array of single crystal CdS nanowires on a porous alumina template. Advanced Materials 13, 1393-1394 (2001).

62. Chen, Y. T., Guo, Y., Kong, L. B. & Li, H. L. A solid-state reaction for the synthesis of CdS nanowires. Chemistry Letters, 602-603 (2002).

63. Gao, F., Lu, Q. Y. & Zhao, D. Y. Ligand-assisted solvothermal growth of CdS nanowires. Chemistry Letters, 732-733 (2002).

64. He, J., Zhao, X. N., Zhu, J. J. & Wang, J. Preparation of CdS nanowires by the decomposition of the complex in the presence of microwave irradiation. Journal of Crystal Growth 240, 389-394 (2002).

65. Klein, J. D. et al. Electrochemical Fabrication of Cadmium Chalcogenide Microdiode Arrays. Chemistry of Materials 5, 902-904 (1993).

66. Li, Y., Wan, J. H. & Gu, Z. N. Templated synthesis of CdS nanowires in hexagonal liquid crystal systems. Acta Physico-Chimica Sinica 15, 1-4 (1999).

67. Li, Y., Wan, J. H. & Gu, Z. N. The formation of cadmium sulfide nanowires in different liquid crystal systems. Materials Science and Engineering a—Structural Materials Properties Microstructure and Processing 286, 106-109 (2000).

68. Peng, X. S. et al. Synthesis of highly ordered CdSe nanowire arrays embedded in anodic alumina membrane by electrodeposition in ammonia alkaline solution. Chemical Physics Letters 343, 470-474 (2001).

69. Tang, K. B., Qian, Y. T., Zeng, J. H. & Yang, X. G. Solvothermal route to semiconductor nanowires. Advanced Materials 15, 448-450 (2003).

70. Wang, Y. H., Xu, Y. Q., Cai, W. L. & Mo, J. M. New method to prepare CdS nanowire arrays. Acta Physico-Chimica Sinica 18, 943-946 (2002).

71. Xie, Y., Yan, P., Lu, J., Qian, Y. T. & Zhang, S. Y. CdS/CdSe core/sheath nanostructures obtained from CdS nanowires. Chemical Communications, 1969-1970 (1999).

72. than, J. H. et al. Polymer-controlled growth of CdS nanowires. Advanced Materials 12, 1348-1351 (2000).

73. Yang, Q., Tang, K. B., Wang, C. R., Qian, Y. T. & Zhang, S. Y. PVA-assisted synthesis, and characterization of CdSe and CdTe nanowires. Journal of Physical Chemistry B 106, 9227-9230 (2002).

74. Zhao, A. W. et al. Electrochemical synthesis of ordered CdTe nanowire arrays. Applied Physics a—Materials Science & Processing 76, 537-539 (2003).

75. Shao, M. W., Kong, L. F., Li, Q., Yu, W. C. & Qian, Y. T. Microwave-assisted synthesis of tube-like HgS nanoparticles in aqueous solution under ambient condition. Inorganic Chemistry Communications 6, 737-739 (2003).

76. Dai, Z. R., Pan, Z. W. & Wang, Z. L. Novel nanostructures of functional oxides synthesized by thermal evaporation. Advanced Functional Materials 13, 9-24 (2003).

77. Wang, Z. L., Pan, Z. W. & Dai, Z. R. Structures of oxide nanobelts and nanowires. Microscopy and Microanalysis 8, 467-474 (2002).

78. Peng, X. S. et al. Novel method synthesis of CdO nanowires. Journal of Physics D—Applied Physics 35, L101-L104 (2002).

79. Han, W. Q., Kohler-Redlich, P., Ernst, F. & Ruhle, M. Growth and microstructure of Ga₂O₃ nanorods. Solid State Communications 115, 527-529 (2000).

80. Hu, J. Q., Li, Q., Meng, X. M., Lee, C. S. & Lee, S. T. Synthesis of beta-Ga₂O₃ nanowires by laser ablation. Journal of Physical Chemistry B 106, 9536-9539 (2002).

81. Gao, Y. H., Bando, Y., Sato, T., Zhang, Y. F. & Gao, X. Q. Synthesis, Raman scattering and defects of beta-Ga₂O₃ nanorods. Applied Physics Letters 81, 2267-2269 (2002).

82. Li, J. Y., Chen, X. L., Zhang, G. & Lee, J. Synthesis and structure of Ga₂O₃ nanosheets. Modern Physics Letters B 16, 409-414 (2002).

83. Patzke, G. R., Krumeich, F. & Nesper, R. Oxidic nanotubes and nanorods—Anisotropic modules for a future nanotechnology. Angewandte Chemie—International Edition 41, 2446-2461 (2002).

84. Li, J. Y., Chen, X. L., Qiao, Z. Y., He, M. & Li, H. Large-scale synthesis of single-crystalline beta-Ga₂O₃ nanoribbons, nanosheets and nanowires. Journal of Physics—Condensed Matter 13, L937-L941 (2001).

85. Cheng, B. & Samulski, E. T. Fabrication and characterization of nanotubular semiconductor oxides In₂O₃ and Ga₂O₃. Journal of Materials Chemistry 11, 2901-2902 (2001).

86. Liang, C. H. et al. Catalytic synthesis and photoluminescence of beta-Ga₂O₃ nanowires. Applied Physics Letters 78, 3202-3204 (2001).

87. Li, J. Y. et al. Synthesis of beta-Ga₂O₃ nanorods. Journal of Alloys and Compounds 306, 300-302 (2000).

88. Zhang, H. Z. et al. Ga₂0₃ nanowires prepared by physical evaporation. Solid State Communications 109, 677-682 (1999).

89. Wu, X. C., Hong, J. M., Han, Z. J. & Tao, Y. R. Fabrication and photoluminescence characteristics of single crystalline In₂O₃ nanowires. Chemical Physics Letters 373, 28-32 (2003).

90. Li, Y. B., Bando, Y. & Golberg, D. Single-crystalline In₂O₃ nanotubes filled with In. Advanced Materials 15, 581-585 (2003).

91. Zhang, J., Qing, X., Jiang, F. H. & Dai, Z. H. A route to Ag-catalyzed growth of the semiconducting In₂O₃ nanowires. Chemical Physics Letters 371, 311-316 (2003).

92. Jepng, J. S., Kim, Y. H. & Lee, J. Y. Morphology and structure of nano-sized In₂O₃ crystals synthesized by wet reaction. Journal of the Korean Physical Society 42, S254-S257 (2003).

93. Li, C. et al. Diameter-controlled growth of single-crystalline In₂O₃ nanowires and their electronic properties. Advanced Materials 15, 143-+(2003).

94. Chen, Y. Q. et al. Bulk-quantity synthesis and self-catalytic VLS growth of SnO₂ nanowires by lower-temperature evaporation. Chemical Physics Letters 369, 16-20 (2003).

95. Li, C. et al. 1n₂0₃ nanowires as chemical sensors. Applied Physics Letters 82, 1613-1615 (2003).

96. Dai, L. et al. Fabrication and characterization of In₂O₃ nanowires. Applied Physics a—Materials Science & Processing 75, 687-689 (2002).

97. Peng, X. S. et al. Synthesis and photoluminescence of single-crystalline In₂O₃ nanowires. Journal of Materials Chemistry 12, 1602-1605 (2002).

98. Peng, X. S. et al. Large-scale synthesis of In₂O₃ nanowires. Applied Physics a—Materials Science & Processing 74, 437-439 (2002).

99. Liang, C. H., Meng, G. W., Lei, Y., Phillipp, F. & Zhang, L. D. Catalytic growth of semiconducting In₂O₃ nanofibers. Advanced Materials 13, 1330-1333 (2001).

100. Liu, Y., Liu, Z. & Wang, G. Preparation of Mn₃O₄ nanowires by calcining the precursor powders synthesized in a novel inverse microemulsion. Applied Physics a—Materials Science & Processing 76, 1117-1120 (2003).

101. Xiong, Y. J., Xie, Y., Li, Z. Q. & Wu, C. Z. Growth of well-aligned gamma-MnO₂ monocrystalline nanowires through a coordination-polymer-precursor route. Chemistry—a European Journal 9, 1645-1651 (2003).

102. Wang, X. & Li, Y. D. Synthesis and formation mechanism of manganese dioxide nanowires/nanorods. Chemistry—a European journal. 9, 300-306 (2003).

103. Xu, C. K., Xu, G. D. & Wang, G. H. Preparation and characterization of NiO nanorods by thermal decomposition of NiC2O4 precursor. Journal of Materials Science 38, 779-782 (2003).

104. Pan, Z. W., Dai, Z. R. & Wang, Z. L. Lead oxide nanobelts and phase transformation induced by electron beam irradiation. Applied Physics Letters 80, 309-311 (2002).

105. Xu, C. K., Zhao, X. L., Liu, S. & Wang, G. H. Large-scale synthesis of rutile SnO₂ nanorods. Solid State Communications 125, 301-304 (2003).

106. Peng, X. S. et al. Micro-Raman and infrared properties of SnO₂ nanobelts synthesized from Sn and SiO₂ powders. Journal of Applied Physics 93, 1760-1763 (2003).

107. Liu, Y. K., Dong, Y. & Wang, G. H. Far-infrared absorption spectra and properties of SnO₂ nanorods. Applied Physics Letters 82, 260-262 (2003).

108. Sun, S. H. et al. Large-scale synthesis of SnO₂ nanobelts. Applied Physics a—Materials Science & Processing 76, 287-289 (2003).

109. Wang, W. Z., Xu, C. K., Wang, G. H., Liu, Y. K. & Zheng, C. L. Synthesis and Raman scattering study of rutile SnO₂ nanowires. Journal of Applied Physics 92, 2740-2742 (2002).

110. Jian, J. K., Chen, X. L., Wang, W. J., Dai, L. & Xu, Y. P. Growth and morphologies of large-scale SnO₂ nanowires, nanobelts and nanodendrites. Applied Physics a—Materials Science & Processing 76, 291-294 (2003).

111. Leite, E. R. et al. Synthesis of Sn0₂ nanoribbons by a carbothermal reduction process. Journal of Nanoscience and Nanotechnology 2, 125-128 (2002).

112. Hu, J. Q. et al. Large-scale rapid oxidation synthesis of SnO₂ nanoribbons. Journal of Physical Chemistry B 106, 3823-3826 (2002).

113. Lyu, S. C. et al. Low temperature growth and photoluminescence of well-aligned zinc oxide nanowires. Chemical Physics Letters 363, 134-138 (2002).

114. Liu, C. H. et al. High-density, ordered ultraviolet light-emitting ZnO nanowire arrays. Advanced Materials 15, 838-+(2003).

115. Yang, P. D. et al. Controlled growth of ZnO nanowires and their optical properties. Advanced Functional Materials 12, 323-331 (2002).

116. Liu, S. C. & Wu, J. J. Low-temperature and catalyst-free synthesis of well-aligned ZnO nanorods on Si (100). Journal of Materials Chemistry 12, 3125-3129 (2002).

117. Tseng, Y. K., Lin, I. N., Liu, K. S., Lin, T. S. & Chen, I. C. Low-temperature growth of ZnO nanowires. Journal of Materials Research 18, 714-718 (2003).

118. Xiao, J. P., Xie, Y., Tang, R. & Luo, W. Template-based synthesis of nanoscale Ag₂E (E =S, Se) dendrites. Journal of Materials Chemistry 12, 1148-1151 (2002).

119. Gates, B., Wu, Y. Y., Yin, Y. D., Yang, P. D. & Xia, Y. N. Single-crystalline nanowires of Ag₂Se can be synthesized by templating against nanowires of trigonal Se. Journal of the American Chemical Society 123, 11500-11501 (2001).

120. Peng, X. S. et al. Electrochemical fabrication of ordered Ag₂S nanowire arrays. Materials Research Bulletin 37, 1369-1375 (2002).

121. Lu, Q. Y., Gao, F. & Zhao, D. Y. Creation of a unique self-supported pattern of radially aligned semiconductor Ag₂S nanorods. Angewandte Chemie—International Edition 41, 1932-+(2002).

122. Glanville, Y. J., Narehood, D. G., Sokol, P. E., Amma, A. & Mallouk, T. Preparation and synthesis of Ag₂Se nanowires produced by template directed synthesis. Journal of Materials Chemistry 12, 2433-2434 (2002).

123. Chen, R. Z., Xu, D. S., Guo, G. L. & Gui, L. L. Silver selenide nanowires by electrodeposition. Journal of the Electrochemical Society 150, G183-G186 (2003).

124. Chen, R. Z., Xu, D. S., Guo, G. L. & Gui, L. L. Silver telluride nanowires prepared by dc electrodeposition in porous anodic alumina templates. Journal of Materials Chemistry 12, 2435-2438 (2002).

125. He, R., Qian, X. F., Yin, J. & Zhu, Z. K.

Preparation of Bi₂S₃ nanowhiskers and their morphologies. Journal of Crystal Growth 252, 505-510 (2003).

126. Zhou, S. X., Li, J. M., Ke, Y. X. & Lu, S. M.

Synthesis of bismuth sulfide nanorods in acidic media at room temperature. Materials Letters 57, 2602-2605 (2003).

127. Shen, G. Z., Chen, D., Tang, K. B., Li, F. Q. & Qian, Y. T. Large-scale synthesis of uniform urchin-like patterns of Bi₂S₃ nanorods through a rapid polyol process. Chemical Physics Letters 370, 334-337 (2003).

128. Wang, D. B., Shao, M. W., Yu, D. B., Li, G. P. & Qian, Y. T. Polyol-mediated preparation of Bi₂S₃ nanorods. Journal of Crystal Growth 243, 331-335 (2002).

129. Wang, H., Zhu, J. J., Zhu, J. M. & Chen, H. Y. Sonochemical method for the preparation of bismuth sulfide nanorods. Journal of Physical Chemistry B 106, 3848-3854 (2002).

130. Peng, X. S. et al. Electrochemical fabrication of ordered Bi₂S₃ nanowire arrays. Journal of Physics D—Applied Physics 34, 3224-3228 (2001).

131. Liao, X. H., Wang, H., Zhu, J. J. & Chen, H. Y. Preparation of Bi₂S₃ nanorods by microwave irradiation. Materials Research Bulletin 36, 2339-2346 (2001).

132. Zhang, W. X. et al. Low temperature growth of bismuth sulfide nanorods by a hydrothermal method. Solid State Communications 119, 143-146 (2001).

133. Yang, J. et al. Pressure-controlled fabrication of stibnite nanorods by the solvothermal decomposition of a simple single-source precursor. Chemistry of Materials 12, 2924-2929 (2000).

134. Yu, S. H. et al. A solvothermal decomposition process for fabrication and particle sizes control of Bi₂S₃ nanowires. Journal of Materials Research 14, 4157-4162 (1999).

135. Wang, D. B., Yu, D. B., Mo, M. S., Liu, X. M. & Qian, Y. T. Preparation and characterization of wire-like Sb₂Se₃ and flake-like Bi₂Se₃ nanocrystals. Journal of Crystal Growth 253, 445-451 (2003).

136. Deng, Y., Wei, G. D. & Nan, C. W. Ligand-assisted control growth of chainlike nanocrystals. Chemical Physics Letters 368, 639-643 (2003).

137. Sander, M. S., Gronsky, R., Sands, T. & Stacy, A. M. Structure of bismuth telluride nanowire arrays fabricated by electrodeposition into porous anodic alumina templates. Chemistry of Materials 15, 335-339 (2003).

138. Peng, Q., Dong, Y. J. & Li, Y. D. Synthesis of uniform CoTe and MiTe semiconductor nanocluster wires through a novel coreduction method. Inorganic Chemistry 42, 2174-2175 (2003).

139. Lu, Q. Y., Gao, F. & Zhao, D. Y. One-step synthesis and assembly of copper sulfide nanoparticles to nanowires, nanotubes, and nanovesicles by a simple organic amine-assisted hydrothermal process. Nano Letters 2, 725-728 (2002).

140. Xu, C. Q., Zhang, Z. C., Ye, Q. & Liu, X. Synthesis of copper sulfide nanowhisker via sonochemical way and its characterization. Chemistry Letters 32, 198-199 (2003).

141. Jun, Y. W., Jung, Y. Y. & Cheon, J. Architectural control of magnetic semiconductor nanocrystals. Journal of the American Chemical Society 124, 615-619 (2002).

142. Li, B., Xie, Y., Huang, J. X., Su, H. L. & Qian, Y. Solvothermal synthesis to NiE₂ (E =Se, Te) nanorods at low temperature. Nanostructured Materials 11, 1067-1071 (1999).

143. Wang, D. B., Yu, D. B., Mo, M. S., Liu, X. M. & Qian, Y. T. Hydrothermal preparation of one-dimensional assemblies of PbS nanoparticles. Solid State Communications 125, 475-479 (2003).

144. Leontidis, E., Orphanou, M., Kyprianidou-Leodidou, T., Krumeich, F. & Caseri, W. Composite nanotubes formed by self-assembly of PbS nanoparticles. Nano Letters 3, 569-572 (2003).

145. Yu, D. B., Wang, D. B., Meng, Z. Y., Lu, J. & Qian, Y. T. Synthesis of closed PbS nanowires with regular geometric morphologies. Journal of Materials Chemistry 12, 403-405 (2002).

146. Chen, M., Xie, Y., Yao, Z. Y., Liu, X. M. & Qian, Y. T. Highly-oriented recrystallization of PbS nanoparticles in a solvothermal process. Materials Chemistry and Physics 74, 109-111 (2002).

147. Qiao, Z. P. et al. Synthesis of lead sulfide/(polyvinyl acetate) nanocomposites with controllable morphology. Chemical Physics Letters 321, 504-507 (2000).

148. Wang, S. H. & Yang, S. H. Preparation and characterization of oriented PbS crystalline nanorods in polymer films. Langmuir 16, 389-397 (2000).

149. Nanda, K. K., Kruis, F. E. & Fissan, H. Energy levels in embedded semiconductor nanoparticles and nanowires. Nano Letters 1, 605-611 (2001).

150. Wang, W. H., Geng, Y., Qian, Y., Ji, M. R. & Liu, X. M. A novel pathway to PbSe nanowires at room temperature. Advanced Materials 10, 1479-1481 (1998).

151. Cho, K. S., Gaschler, W. L., Murray, C. B. & Stokes, K. L. PBSE nanocrystals, nanowires and superlattices. Abstracts of Papers of the American Chemical Society 224, U308-U308 (2002).

152. Chen, M., Xie, Y., Lu, J. C., Zhu, Y. J. & Qian, Y. T. A novel two-step radiation route to PbSe crystalline nanorods. Journal of Materials Chemistry 11, 518-520 (2001).

153. An, C. H. et al. Shape-selected synthesis of nanocrystalline SnS in different alkaline media. Journal of Crystal Growth 252, 581-586 (2003).

154. Shen, G. Z. et al. Rapid synthesis of SnSe nanowires via an ethylenediamine-assisted polyol route. Chemistry Letters 32, 426-427 (2003).

155. Jiang, Y. et al. Elemental solvothermal reaction to produce ternary semiconductor CuInE₂ (E=S, Se) nanorods. Inorganic Chemistry 39, 2964-+ (2000).

156. Jin, Y., Tang, K. B., An, C. H. & Huang, L. Y. Hydrothermal synthesis and characterization of AgInSe₂ nanorods. Journal of Crystal Growth 253, 429-434 (2003).

157. Zhou, S. M., Feng, Y. S. & Zhang, L. D. Growth and optical characterization of large-scale crystal CdₓZn₁₋ₓS whiskers via vapor reaction. Journal of Crystal Growth 252, 1-3 (2003).

158. Joo, J. et al. Conducting polymer nanotube and nanowire synthesized by using nanoporous template: Synthesis, characteristics, and applications. Synthetic Metals 135, 7-9 (2003).

159. He, H. X., Li, C. Z. & Tao, N. J. Conductance of polymer nanowires fabricated by a combined electrodeposition and mechanical break junction method. Applied Physics Letters 78, 811-813 (2001).

160. Choi, S. J. & Park, S. M. Electrochemical growth of nanosized conducting polymer wires on gold using molecular templates. Advanced Materials 12, 1547-1549 (2000).

161. Hassanien, A., Gao, M., Tokumoto, M. & Dai, L. Scanning tunneling microscopy of aligned coaxial nanowires of polyaniline passivated carbon nanotubes. Chemical Physics Letters 342, 479-484 (2001).

162. Huang, K. & Wan, M. X. Self-assembled nanostructural polyaniline doped with azobenzenesulfonic acid. Synthetic Metals 135, 173-174 (2003).

163. Wan, M. X. et al. Studies on nanostructures of conducting polymers via self-assembly method. Synthetic Metals 135, 175-176 (2003).

164. Huang, J. X., Virji, S., Weiller, B. H. & Kaner, R. B. Polyaniline nanofibers: Facile synthesis and chemical sensors. Journal of the American Chemical Society 125, 314-315 (2003).

165. He, C., Tan, Y. W. & Li, Y. F. Conducting polyaniline nanofiber networks prepared by the doping induction of camphor sulfonic acid. Journal of Applied Polymer Science 87, 1537-1540 (2003).

166. Kahol, P. K. & Pinto, N. J. Electron paramagnetic resonance investigations of electrospun polyaniline fibers. Solid State Communications 124, 195-197 (2002).

167. Huang, K. & Wan, M. X. Self-assembled polyaniline nanostructures with photoisomerization function. Chemistry of Materials 14, 3486-3492 (2002).

168. Ikegame, M., Tajima, K. & Aida, T. Template synthesis of polypyrrole nanofibers insulated within one-dimensional silicate channels: Hexagonal versus lamellar for recombination of polarons into bipolarons. Angewandte Chemie—International Edition 42, 2154-2157 (2003).

169. Duvail, J. L. et al. Physical properties of conducting polymer nanofibers. Synthetic Metals 135, 329-330 (2003).

170. MacDiarmid, A. G. et al. Electrostatically-generated nanofibers of electronic polymers. Synthetic Metals 119, 27-30 (2001).

171. Sailor, M. J. & Curtis, C. L. Conducting Polymer Connections for Molecular Devices. Advanced Materials 6, 688-692 (1994).

172. Zhang, F. L., Nyberg, T. & Inganas, 0. Conducting polymer nanowires and nanodots made with soft lithography. Nano Letters 2, 1373-1377 (2002).

173. Duvail, J. L. et al. Transport and vibrational properties of poly(3,4-ethylenedioxythiophene) nanofibers. Synthetic Metals 131, 123-128 (2002).

174. Chen, S. H., Fan, Z. Y. & Carroll, D. L. Silver nanodisks: Synthesis, characterization, and self-assembly. Journal of Physical Chemistry B 106, 10777-10781 (2002).

175. Coleman, N. R. B. et al. Synthesis and characterization of dimensionally ordered semiconductor nanowires within mesoporous silica. Journal of the American Chemical Society 123, 7010-7016 (2001).

176. Flahaut, E., Agnoli, F., Sloan, J., O'Connor, C. & Green, M. L. H. CCVD synthesis and characterization of cobalt-encapsulated nanoparticles. Chemistry of Materials 14, 2553-2558 (2002).

177. Gao, S. M. et al. Mild benzene-thermal route to GaP nanorods and nanospheres. Inorganic Chemistry 41, 1850-1854 (2002).

178. He, R., Qian, X. F., Yin, J. & Zhu, Z. K. Preparation of polychrome silver nanoparticles in different solvents. Journal of Materials Chemistry 12, 3783-3786 (2002).

179. Hu, J. Q., Deng, B., Zhang, W. X., Tang, K. B. & Qian, Y. T. Synthesis and characterization of CdIn2S4 nanorods by converting CdS nanorods via the hydrothermal route. Inorganic Chemistry 40, 3130-3133 (2001).

180. Li, G. L., Wang, G. H. & Hong, J. M. Synthesis and characterization of rutile TiO₂ nanowhiskers. Journal of Materials Research 14, 3346-3354 (1999).

181. Li, L. S. & Alivisatos, A. P. Semiconductor nanorod liquid crystals and their assembly on a substrate. Advanced Materials 15, 408-+(2003).

182. Li, W. J. et al. Hydrothermal synthesis of MoS₂ nanowires. Journal of Crystal Growth 250, 418-422 (2003).

183. Lifshitz, E. et al. Synthesis and characterization of PbSe quantum wires, multipods, quantum rods, and cubes. Nano Letters 3, 857-862 (2003).

184. Liu, Y. F. et al. Hydrothermal synthesis of square thin flake CdS by using surfactants and thiocarbohydrate. Materials Research Bulletin 36, 1231-1236 (2001).

185. Mayers, B. & Xia, Y. N. One-dimensional nanostructures of trigonal tellurium with various morphologies can be synthesized using a solution-phase approach. Journal of Materials Chemistry 12, 1875-1881 (2002).

186. Shao, M. W. et al. Microwave-templated synthesis of CdS nanotubes in aqueous solution at room temperature. New Journal of Chemistry 26, 1440-1442 (2002).

187. Shen, G. Z., Chen, D., Tang, K. B., Jiang, X. & Qian, Y. T. A rapid ethylenediamine-assisted polyol route to synthesize Sb2E3 (E=S, Se) nanowires. Journal of Crystal Growth 252, 350-354 (2003).

188. Wu, S. D., Zhu, Z. G., Zhang, Z. P. & Zhang, L. Preparation of the US semiconductor nanofibril by UV irradiation. Materials Science and Engineering B—Solid State Materials for Advanced Technology 90, 206-208 (2002).

189. Xu, J. & Li, Y. D. Formation of zinc sulfide nanorods and nanoparticles in ternary W/O microemulsions. Journal of Colloid and Interface Science 259, 275-281 (2003).

190. Yin, Y. D., Lu, Y., Sun, Y. G. & Xia, Y. N. Silver nanowires can be directly coated with amorphous silica to generate well-controlled coaxial nanocables of silver/silica. Nano Letters 2, 427-430 (2002).

191. Yu, S. H. et al. In situ fabrication and optical properties of a novel polystyrene/semiconductor nanocomposite embedded with CdS nanowires by a soft solution processing route. Langmuir 17, 1700-1707 (2001).

192. Zhou, H. C., Xu, J., Xu, S. & Li, Y. D. Synthesis and characterization of CaSO₄ nanorods (wires) in microemulsion system. Chinese Journal of Inorganic Chemistry 18, 815-818 (2002).

193. Zhou, S. M., Feng, Y. S. & Zhang, L. D. Sonochemical synthesis of large-scale single crystal CdS nanorods. Materials Letters 57, 2936-2939 (2003).

194. Zhu, J. J., Wang, H., Zhu, J. M. & Wang, J. A rapid synthesis route for the preparation of CdS nanoribbons by microwave irradiation. Materials Science and Engineering B—Solid State Materials for Advanced Technology 94, 136-140 (2002).

195. Yang, P. D. & Kim, F. Langmuir-Blodgett assembly of one-dimensional nanostructures. Chemphyschem 3, 503-+ (2002).

196. Reitzel, N. et al. Langmuir and Langmuir-Blodgett films of amphiphilic hexa-peri-hexabenzocoronene: New phase transitions and electronic properties controlled by pressure. Chemistry—a European Journal 7, 4894-4901 (2001).

197. Liu, J. F., Yang, K. Z. & Lu, Z. H. Controlled assembly of regular composite nanowire arrays and their multilayers using electropolymerized polymers as templates. Journal of the American Chemical Society 119, 11061-11065 (1997).

198. Wang, Z. L. & Pan, Z. W. Junctions and networks of SnO nanoribbons. Advanced Materials 14, 1029-+(2002).

199. Li, D. & Xia, Y. N. Fabrication of titania nanofibers by electrospinning. Nano Letters 3, 555-560 (2003).

200. Theron, A., Zussman, E. & Yarin, A. L. Electrostatic field-assisted alignment of electrospun nanofibres. Nanotechnology 12, 384-390 (2001).

201. Dekker, C. Carbon nanotubes as molecular quantum wires. Physics Today 52, 22-28 (1999).

202. Snow, E. S., Novak, J. P., Campbell, P. M. & Park, D. Random networks of carbon nanotubes as an electronic material. Applied Physics Letters 82, 2145-2147 (2003).

#727396v1

1. An electronic device, comprising:
a source electrode;
a drain electrode spaced apart from said source electrode; and
at least one of a conducting material, dielectric material and a semiconductor material disposed between said source electrode and said drain electrode,
wherein at least one of said source electrode, said drain electrode and said semiconductor material comprises a nanowire.

2. An electronic device according to claim 1, wherein said at least one of said source electrode, said drain electrode and said semiconductor material comprises a network of nanowires.

3. An electronic device according to claim 2, wherein said network of nanowires are embedded in a matrix material to form a composite material.

4. An electronic device according to claim 1, wherein said at least one of said conducting material, said dielectric material and said semiconductor material disposed between said source electrode and said drain electrode is a dielectric material so that said electronic device is a capacitor.

5. An electronic device according to claim 1, wherein said at least one of said conducting material, said dielectric material and said semiconductor material disposed between said source electrode and said drain electrode is a semiconductor material so that said electronic device is a diode.

6. An electronic device according to claim 1, wherein said at least one of said conducting material, said dielectric material and said semiconductor material disposed between said source electrode and said drain electrode is a conducting material to provide a conducting channel between said source electrode and said drain electrode so that said electronic device is at least one of a resistor, an inductor and a transistor.

7. An electronic device according to claim 6, further comprising a gate electrode disposed proximate said conducting channel so that said electronic device is a transistor.

8. An electronic device according to claim 7, further comprising an insulating layer disposed on said gate electrode,
wherein said conducting channel is disposed on said insulating layer, and said source electrode and said drain electrode are disposed on said conducting channel to provide a bottom-gated transistor.

9. An electronic device according to claim 7, further comprising an insulating layer disposed on said source electrode, said drain electrode and said conducting channel,
wherein said gate electrode is disposed on said insulating layer to provide a top-gated transistor.

10. An electronic device according to claim 7, further comprising:
an insulating layer upon which said source electrode, said drain electrode, said gate electrode and said conducting channel are formed; and
a second gate electrode formed on said insulating layer spaced apart from the first-mentioned gate electrode with said conducting channel arranged therebetween to provide a side-gated transistor.

11. An electronic device according to claim 7, further comprising a drop of electrolyte disposed on said source electrode, said drain electrode and said conducting channel,
wherein said gate electrode is in electrical contact with said drop of electrolyte to provide a liquid-gated transistor.

12. An electronic device according to claim 1, wherein said nanowire is a carbon nanotube.

13. An electronic device according to claim 2, wherein said network of nanowires is a network of carbon nanotubes.

14. An electronic device according to claim 1, wherein said source electrode and said drain electrode both comprise networks of nanowires.

15. An electronic device according to claim 6, wherein said source electrode, said drain electrode and said conducting channel all comprise nanowires.

16. An electronic device according to claim 7, wherein said source electrode, said drain electrode, said gate electrode and said conducting channel all comprise nanowires.

17. A method of manufacturing an electronic device, comprising:
forming a source electrode;
forming a drain electrode spaced apart from said source electrode; and
providing at least one of a conducting material, dielectric material and a semiconductor material between said source electrode and said drain electrode,
wherein at least one of said source electrode, said drain electrode and said semiconductor material comprises a nanowire.

18. A method of manufacturing an electronic device according to claim 17, wherein said at least one of said conducting material, said dielectric material and said semiconductor material between said source electrode and said drain electrode is a conducting material to provide a conducting channel between said source electrode and said drain electrode so that said electronic device is at least one of a resistor, an inductor and a transistor.

19. A method of manufacturing an electronic device according to claim 18, further comprising forming a gate electrode proximate said conducting channel so that said electronic device is a transistor.
